(19) United States
(12) Patent Application Publication
(10) Pub. No.: US 2026/0114013 A1
(43) Pub. Date: Apr. 23, 2026

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventors: Ta-Chun LIN, Hsinchu (TW); Ming-Heng TSAI, Taipei City (TW); Hong-Chih CHEN, Changhua County (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/920,365

(22) Filed: Oct. 18, 2024

(51) Int. Cl. H01L 29/417; H01L 29/06; H01L 29/423; H01L 29/66; H01L 29/775; H01L 29/786

(52) U.S. Cl. CPC H10D 64/258; H10D 30/014; H10D 30/43; H10D 30/6729; H10D 30/6735; H10D 30/6757; H10D 62/121; H10D 64/017

(57) ABSTRACT

A method of forming a semiconductor device includes a number of operations. A plurality of channel layers is vertically arranged over a substrate. Source/drain regions are formed on opposite sides of the channel layers. A gate structure is formed and wraps around the channel layers. A planarization process is performed on the gate structure such that a first portion of the gate structure above a topmost one of the channel layers has a first height less than a second height of a second portion of the gate structure between the channel layers. Source/drain contacts are formed over the source/drain regions.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9B illustrate schematic views of intermediate stages in the manufacture of a semiconductor device in accordance with some embodiments of the present disclosure.

FIG. 10 is a cross-sectional view of a semiconductor device in accordance with some embodiments of the present disclosure.

FIG. 11 is a cross-sectional view of a semiconductor device in accordance with some embodiments of the present disclosure.

FIG. 12 is a cross-sectional view of a semiconductor device in accordance with some embodiments of the present disclosure.

FIG. 13 is a cross-sectional view of a semiconductor device in accordance with some embodiments of the present disclosure.

FIG. 14 is a cross-sectional view of a semiconductor device in accordance with some embodiments of the present disclosure.

FIG. 15 is a cross-sectional view of a semiconductor device in accordance with some embodiments of the present disclosure.

FIG. 16 is a cross-sectional view of a semiconductor device in accordance with some embodiments of the present disclosure.

FIG. 17 is a cross-sectional view of a semiconductor device in accordance with some embodiments of the present disclosure.

FIGS. 18A and 18B are cross-sectional views of a semiconductor device in accordance with some embodiments of the present disclosure.

FIG. 19 is a cross-sectional view of a semiconductor device in accordance with some embodiments of the present disclosure.

FIGS. 20-21 illustrate schematic views of intermediate stages in the manufacture of a semiconductor device in accordance with some embodiments of the present disclosure.

FIG. 22 is a cross-sectional view of a semiconductor device in accordance with some embodiments of the present disclosure.

FIG. 23 is a cross-sectional view of a semiconductor device in accordance with some embodiments of the present disclosure.

FIG. 24 is a cross-sectional view of a semiconductor device in accordance with some embodiments of the present disclosure.

FIG. 25 illustrates cross-sectional views of a p-type FET region and an n-type FET region of a semiconductor device in accordance with some embodiments of the present disclosure.

FIG. 26 illustrates cross-sectional views of a memory region and a logic region of a semiconductor device in accordance with some embodiments of the present disclosure.

FIG. 27 is a cross-sectional view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure. In some embodiments, the GAA device may have fork-sheet structures.

Various embodiments of the present disclosure related to GAA devices with gate structures having outer gate portions above the topmost channel layers and inner gate portions between the channel layers. In one or more embodiments of the present disclosure, vertical dimensions of the outer gate portions above the topmost channel layers is substantially equal to or less than the vertical dimensions of the inner gate portions between the channel layers. The laterally overlapping area between the outer gate portions and the adjacent source/drain contacts can be reduced, and thus the effective parasitic capacitance caused by the outer gate portions and the adjacent source/drain contacts can be also reduced. In some embodiments, the topmost surfaces of the gate structures may be lower than the topmost surfaces of the adjacent source/drain contacts. In some embodiments, the vertical dimension of the outer gate portions of the gate structures can be controlled so that the outer gate portions of the gate structures at different area may have different vertical dimensions.

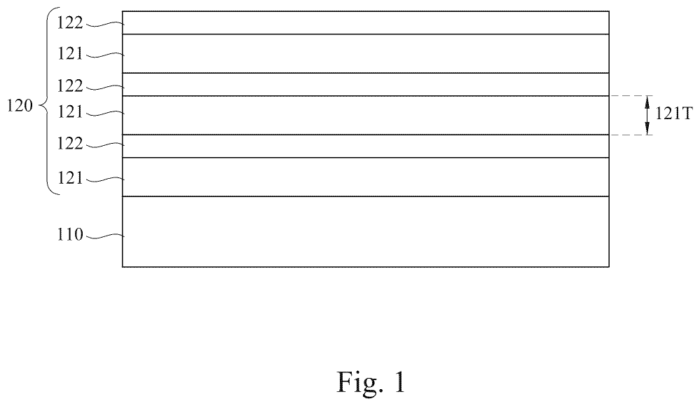

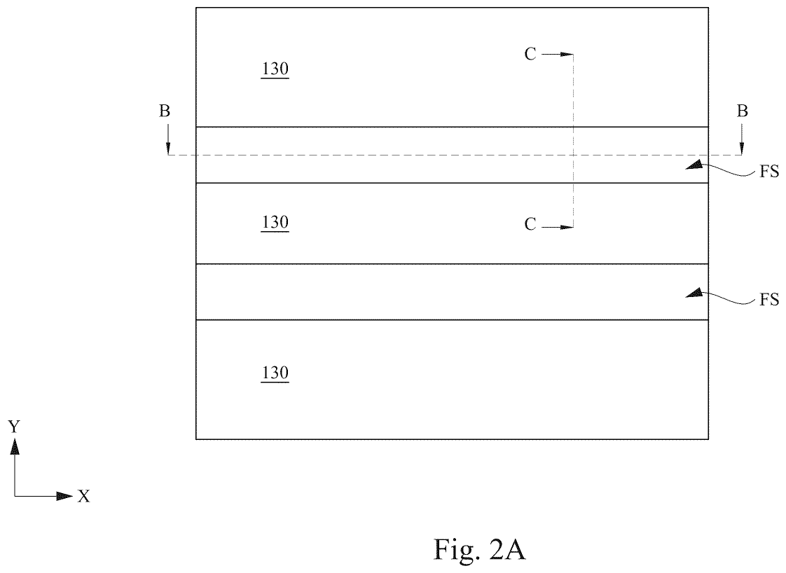

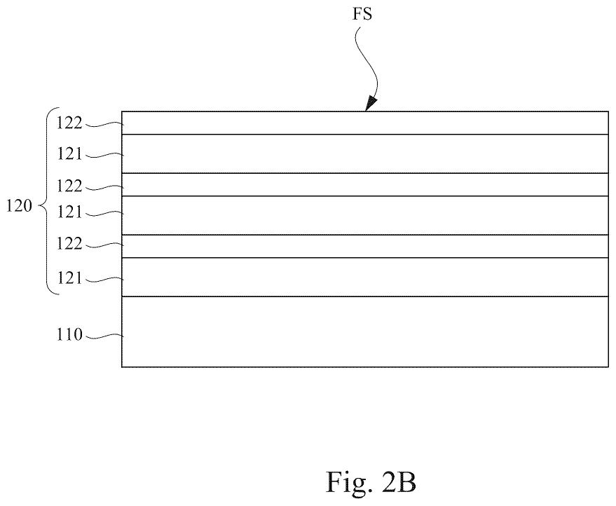

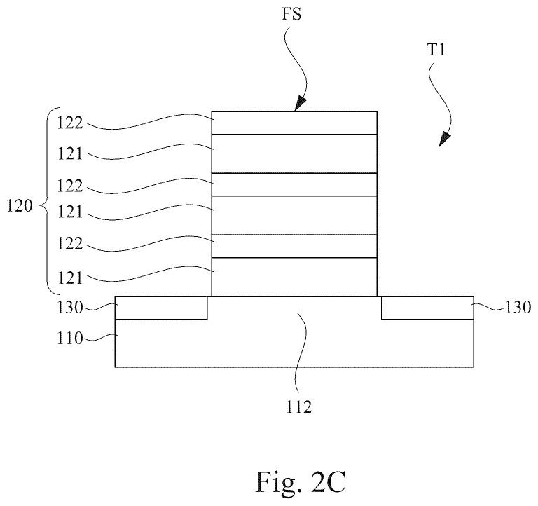

FIGS. 1-9B illustrate schematic views of intermediate stages in the formation of a semiconductor device in accordance with some embodiments of the present disclosure. FIGS. 2A, 3A, 5A, 6A, and 7A are top views of the semiconductor device at various manufacturing stages in accordance with some embodiments. FIGS. 1, 2B, 3B, 4, 5B, 6B, 7B, 8 and 9A are cross-sectional views of the semiconductor device (e.g., taken along line B-B in FIGS. 2A, 3A, 5A, 6A, and 7A) at various manufacturing stages in accordance with some embodiments. FIGS. 2C, 3C, 6C, 7C and 9B are cross-sectional views of the semiconductor device (e.g., taken along line C-C in FIGS. 2A, 3A, 6A, and 7A) at various manufacturing stages in accordance with some embodiments. It is understood that additional steps may be provided before, during, and after the steps shown in FIGS. 1-9B, and some of the steps described below can be replaced or eliminated for additional embodiments of the method. The order of the operations/processes may be interchangeable.

Reference is made to FIG. 1. An epitaxial stack 120 is formed over a substrate 110. In some embodiments, the substrate 110 includes silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 includes a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

As illustrated in FIG. 1, the epitaxial stack 120 includes sacrificial layers 121 and channel layers 122 alternatively arranged with each other. The sacrificial layers 121 may have different semiconductor compositions from the channel layers 122. In some embodiments, the sacrificial layers 121 and the channel layers 122 include SiGe with various semiconductor compositions. For example, a Si concentration in the sacrificial layers 121 is less than a Si concentration in the channel layers 122. Stated differently, in the embodiments, a Ge concentration in the sacrificial layers 121 is greater than a Ge concentration in the channel layers 122. For example, the channel layers 122 are SiₓGe₁₋ₓ, and the sacrificial layers 121 are Si_{y}Ge_{1-y}, in which x and y are in a range from 0 to 1, and x>y. However, other embodiments are possible including those that provide for the material/compositions having different oxidation rates and/or etch selectivity. In some embodiments where the sacrificial layers 121 include SiGe and the channel layers 122 include Si, the Si oxidation rate of the channel layers 122 is less than the SiGe oxidation rate of the sacrificial layers 121.

The channel layers 122 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 122 may be referred to as semiconductor channels in the context. The use of the channel layers 122 to define a channel or channels of a device is further discussed below. In the depicted embodiments, the number of the channel layers 122 is three. In various embodiments, the number of the channel layers 122 can be 1, 2, 3 or more. For example, the number of the channel layers 122 may vary in a range from 1 to 10.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the channel layers 122 include suitable semiconductor material, such as like Si, Ge, Sn, SiGe, GeSn, III-V semiconductor, the like, or the combination thereof. In some embodiments, the channel layers 122 include a same semiconductor material as that of the substrate 110. In some embodiments, the epitaxially grown sacrificial layers 121 include a different material than the substrate 110. For example, the sacrificial layers 121 include suitable semiconductor material, such as Si, Ge, SiGe, GeSn, III-V semiconductor, the like, or the combination thereof. In some other embodiments, at least one of the sacrificial layers 121 and the channel layers 122 includes other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the sacrificial layers 121 and the channel layers 122 may be chosen based on providing differing oxidation and/or etching selectivity properties. In some embodiments, the sacrificial layers 121 and the channel layers 122 are intrinsic semiconductor layers, which are not intentionally doped, for example, not having intentionally placed dopants, but rather having a doping resulting from process contaminants. In some embodiments, the sacrificial layers 121 and the channel layers 122 are substantially dopant-free (i.e., having an extrinsic dopant concentration from about 0 cm⁻³ to about 1×10¹⁸ cm⁻³), where for example, no intentional doping is performed during the epitaxial growth process.

In some embodiments, a thickness 121T of the sacrificial layers 121 may determine the spaces between the channel layers 122.

Reference is made to FIGS. 2A, 2B and 2C. A plurality of semiconductor fins FS extending from the substrate 110 is formed. The semiconductor fins FS may extend substantially along a direction X. In various embodiments, each of the fins FS includes a substrate portion 112 formed from the substrate 110 and portions of each of the epitaxial layers of the epitaxial stack 120 including epitaxial layers 121 and 122. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

The fins FS may be fabricated using suitable processes including photolithography and etch processes. The photolithography process may include forming a photoresist layer (not shown), exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches T1 in unprotected regions through the epitaxial stack 120, and into the substrate 110, thereby leaving the plurality of extending fins FS. The trenches T1 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS.

After the formation of the fins FS, an isolation structure 130 is formed in the trench T1 between the fins FS. The isolation structure 130 may be a single-layer or a multi-layer structure. In some embodiments, the isolation structure 130 includes low-k dielectric materials, SiN, SiCN, SiOC, SiOCN or the like. Formation of the isolation structure 130 may include depositing a dielectric material into the trench T1, followed by an etching back process. Through the etching back process, a top surface of the isolation structure 130 may be level with or lower than a bottom surface of the epitaxial stack 120. In some alternatively embodiments, the top surface of the isolation structure 130 is higher than the bottom surface of the epitaxial stack 120.

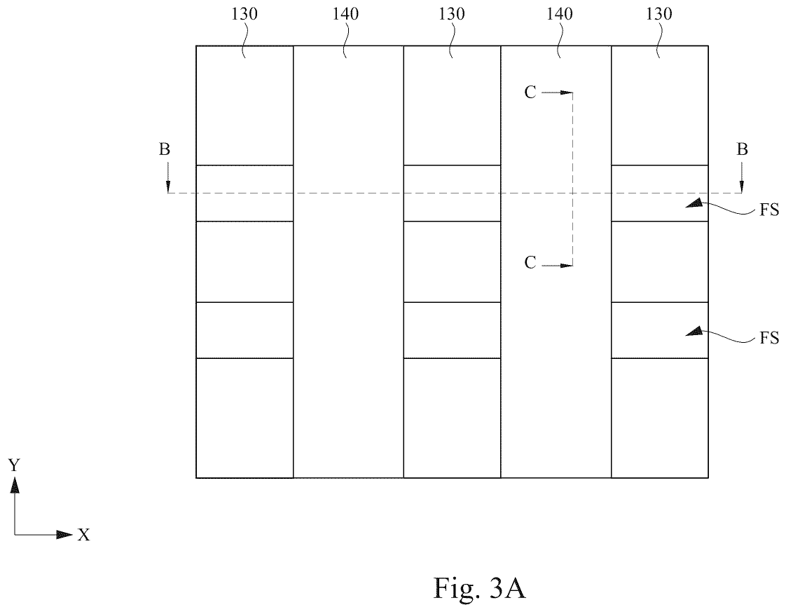

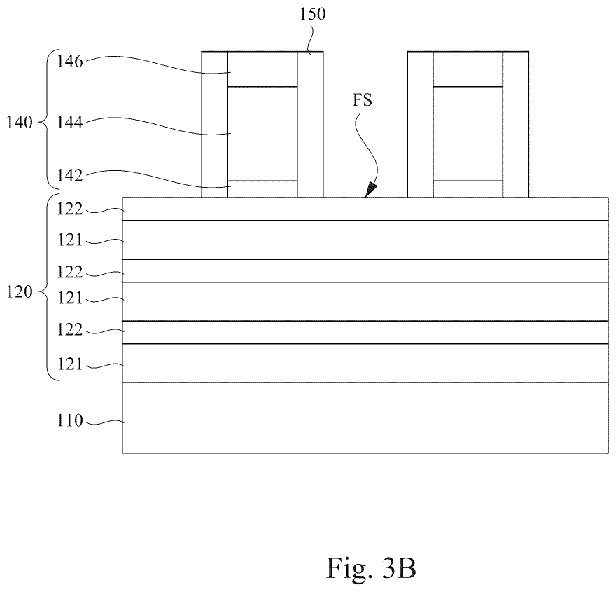

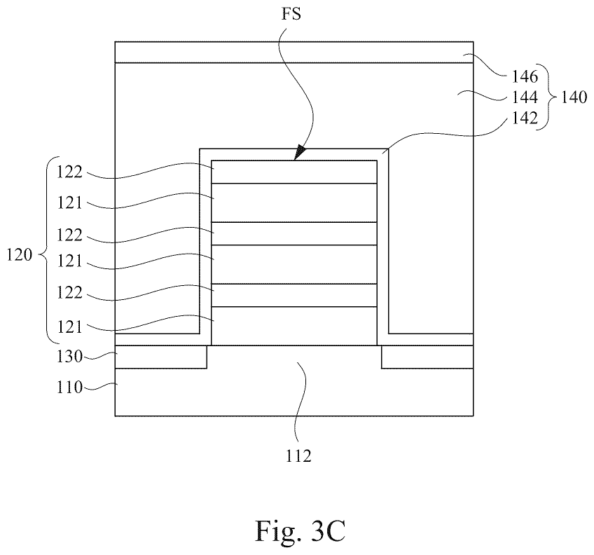

Reference is made to FIGS. 3A-3C. One or more dummy gate structures 140 are formed on the epitaxial stack 120. The dummy gate structure 140 may include a gate dielectric 142, a gate electrode 144, and a hard mask 146. The gate dielectric 142 may include one or more layers of dielectric material, such as silicon oxide, silicon nitride, a high-k dielectric material, and/or other suitable dielectric material. In some embodiments, the gate electrode 144 includes a material different than that of the gate dielectric 142. In some embodiments, the gate dielectric 142 may be deposited by a CVD process, a sub-atmospheric CVD (SACVD) process, a FCVD process, an ALD process, a PVD process, or other suitable process. The gate electrode 144 may include polycrystalline silicon (polysilicon). The hard mask 146 may include a silicon oxide layer and a silicon nitride layer. In some embodiments, the materials of the dummy gate structures 140 are formed by various processes such as layer deposition, for example, CVD, PVD, ALD, thermal oxidation, or other suitable deposition techniques, or combinations thereof.

The dummy gate structures 140 may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure 140.

Gate spacers 150 are formed on opposite sidewalls of the dummy gate structures 140. The gate spacer 150 may be made of a dielectric material such as silicon oxide, silicon nitride, silicon carbide, silicon oxynitride, SiCN, silicon oxycarbide, SiOCN, and/or combinations thereof. The gate spacers 150 may be formed by first depositing one or more conformal spacer material layers and subsequently etching back the one or more spacer material layers to form gate spacers 150. The one or more conformal spacer material layers may be formed by ALD or CVD processes. The etching back process may include an anisotropic dry etch process. During the anisotropic dry etch process, most of the one or more spacer material layers are removed from horizontal surfaces, such as the tops of the fins FS, leaving the gate spacers 150 on the vertical surfaces, such as the sidewalls of the dummy gate structures 140.

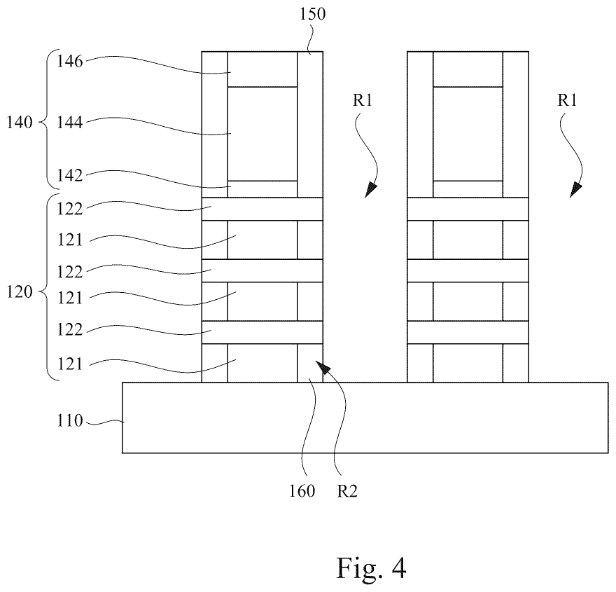

Reference is made to FIG. 4. Exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS. The recesses R1 may extend through the epitaxial layers 121 and 122. After the anisotropic etching, end surfaces of the epitaxial layers 121 and 122 are exposed and aligned with respective outermost sidewalls of the gate spacers 150, due to the anisotropic etching.

The sacrificial layers 121 are laterally or horizontally recessed by using suitable selective etching process, resulting in lateral/sidewall recesses R2 vertically between corresponding channel layers 122. For example, end surfaces of the sacrificial layers 121 are laterally recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The layers 122 may have a higher etch resistance to the selective etching process than that of the sacrificial layers 121. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 122 may not be significantly etched by the process of laterally recessing the sacrificial layers 121. As a result, the layers 122 laterally extend past opposite end surfaces of the sacrificial layers 121.

Inner spacers 160 are formed in the recesses R2. Stated differently, the inner spacers 160 may be formed on opposite end surfaces of the laterally recessed sacrificial layers 121. The inner spacers 160 may include a dielectric material, such as SiOₓ, SiON, SiOC, SiN, SiCN, or SiOCN. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left. The inner spacers 160 may include a single layer or multiple layers. The inner spacers 160 may serve to isolate metal gates from source/drain regions formed in subsequent processing. In the example of FIG. 4, sidewalls of the inner spacers 160 are aligned with sidewalls of the channel layers 122.

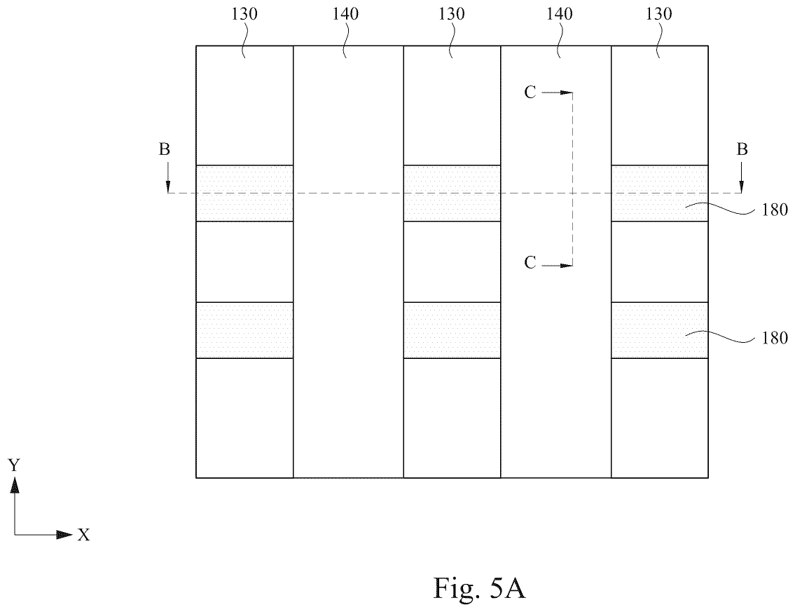

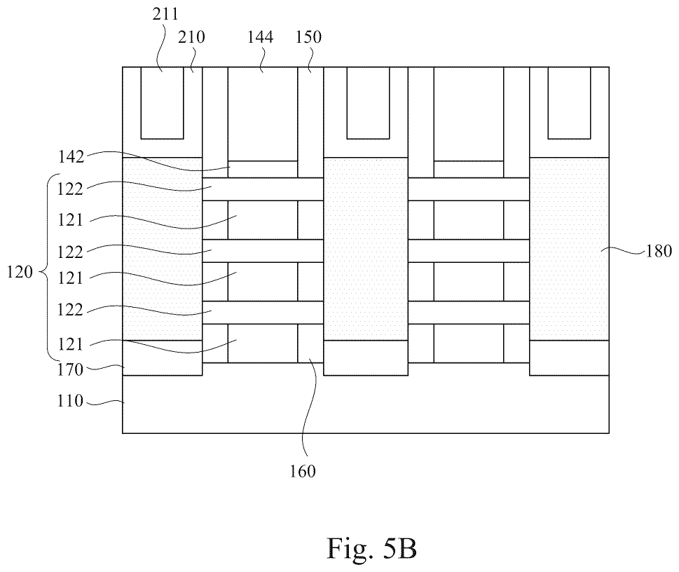

Reference is made to FIGS. 5A and 5B. Source/drain epitaxial structures 180 are formed in the recesses R1 on opposite sides of the channel layers 122 and on opposite sides of the dummy gate structure 140. The source/drain epitaxial structures 180 may be in contact with the exposed end surfaces of the channel layers 122. In some embodiments, the source/drain epitaxial structures 180 may include Ge, Si, GaAs, AlGaAs, SiGe, GaAsP, SiP, or other suitable material. The source/drain epitaxial structures 180 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 180 are not in-situ doped, an implantation process (i.e., a junction implant process) is performed to dope the source/drain epitaxial structures 180. The source/drain epitaxial structures 180 may be formed by performing an epitaxial growth process that provides an epitaxial material on the exposed surfaces of the channel layers 122. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the epitaxial layers 122.

In some embodiments, prior to the formation of the source/drain epitaxial structures 180, bottom isolation layers 170 are formed in the recesses R1, respectively. In some embodiments, the bottom isolation layer 170 includes SiN, SiO₂, SiON, SiCN, SiCON, SiCO, high-k dielectrics (e.g., HfO, AlO, etc.), other low-k dielectric materials, the like, or the combination thereof. The bottom isolation layer 170 may be a single-layer or a multi-layer structure. In some embodiments, formation of the bottom isolation layers 170 may include depositing a dielectric material over the recesses R1, followed by etching back the dielectric material to form the bottom isolation layers 170. In some embodiments, the bottom isolation layer 170 may be deposited by suitable CVD, ALD process, the like, or the combination thereof. The bottom isolation layer 170 may serve to isolate the source/drain epitaxial structures 180 from the substrate 110. In some alternative embodiments, the bottom isolation layers 170 are omitted, and the source/drain epitaxial structures 180 are in contact with the substrate 110.

After the formation of the source/drain epitaxial structures 180, dielectric material are formed over the substrate 110 and filling the space around the dummy gate structures 140. In some embodiments, the dielectric material includes a contact etch stop layer (CESL) 210 and an interlayer dielectric (ILD) layer 211 formed in sequence. In some examples, the CESL layer 210 includes a silicon nitride layer, silicon oxide layer, a silicon oxynitride layer, and/or other suitable. The ILD layer 211 is then deposited over the CESL layer 210. In some embodiments, the ILD layer 211 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL layer 210. The ILD layer 211 may be deposited by a CVD process or other suitable deposition technique. In some embodiments, after formation of the ILD layer 211, the semiconductor device may be subject to a high thermal budget process to anneal the ILD layer 211. After depositing the ILD layer 211, a planarization process may be performed to remove excessive materials of the CESL 210 and the ILD layer 211. For example, a planarization process includes a chemical mechanical polish (CMP) process which removes portions of the CESL 210 and the ILD layer 211 overlying the dummy gate structures 140 and planarizes a top surface of the semiconductor device. The planarization process may also remove the hard mask 146 (referring to FIG. 4), which leaves the dummy gate electrode 144 exposed.

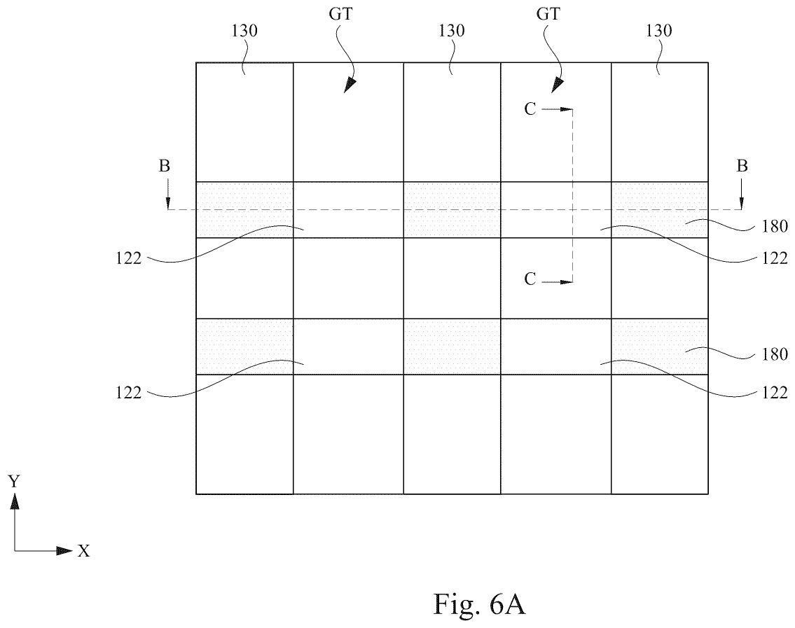

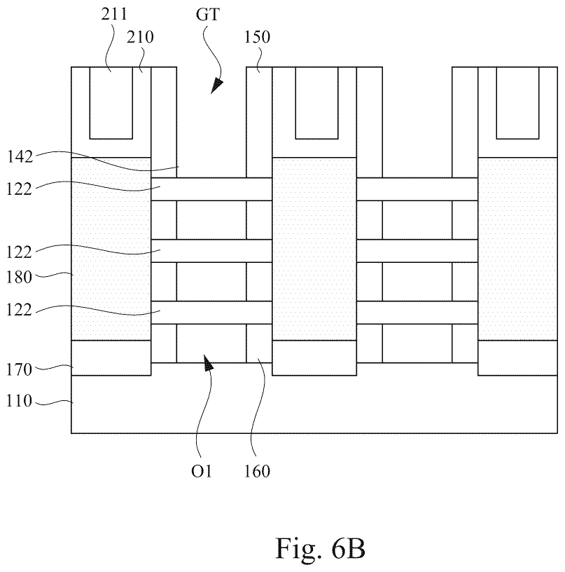

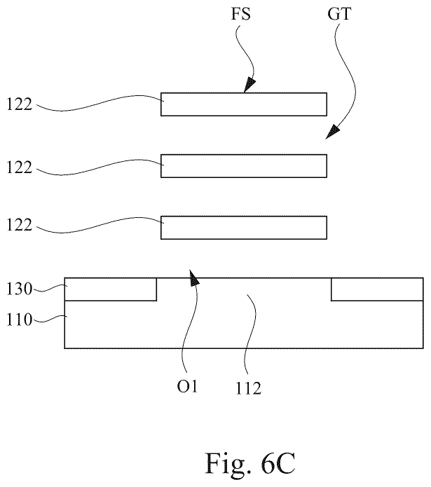

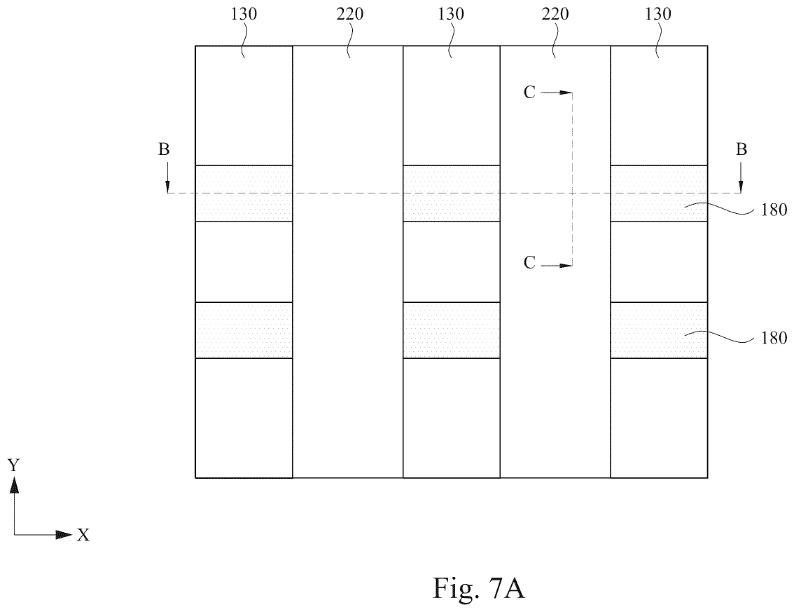

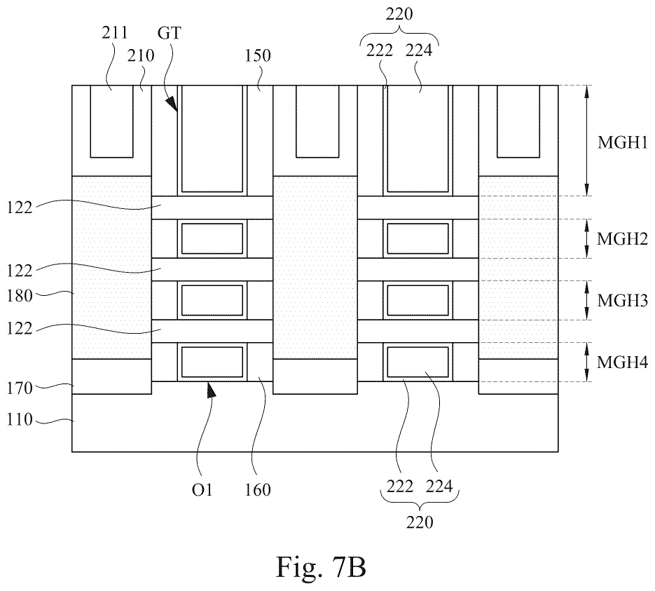

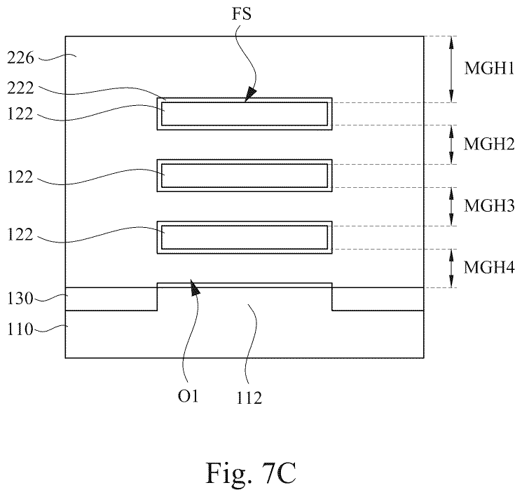

Reference is made to FIGS. 6A-7C. The dummy gate structure 140 and the sacrificial layer 121 (referring to FIG. 5B) are replaced with high-k/metal gate structures 220. In FIGS. 6A-6C, the dummy gate structure 140 (referring to FIG. 5B) is removed, followed by removing the sacrificial layers 121 (referring to FIG. 5B). In some embodiments, the dummy gate structure 140 (referring to FIG. 5B) is removed by using a selective etching process (e.g., selective dry etching, selective wet etching, or a combination thereof) that etches the materials in dummy gate structures 140 (referring to FIG. 4) at a faster etch rate than it etches other materials (e.g., gate spacers 150 and/or the dielectric material including the CESL layer 210 and the ILD layer 211), thus resulting in a gate trench GT between corresponding gate spacers 150, with the sacrificial layers 121 (referring to FIG. 5B) exposed in the gate trench GT. Subsequently, the sacrificial layers 121 (referring to FIG. 5B) in the gate trench GT are etched by using another selective etching process that etches the sacrificial layers 121 (referring to FIG. 5B) at a faster etch rate than it etches the layers 122, thus respectively forming openings/spaces O1 between the channel layers 122. The openings/spaces O1 may expose the sidewalls of the inner spacers 160. In this way, the channel layers 122 become nanosheets suspended over the substrate 110 and between the source/drain epitaxial structures 180. This step is also called a channel release process.

At this interim processing step, the openings/spaces O1 surrounding the nanosheets 122 may be filled with ambient environment conditions (e.g., air, nitrogen, etc). In some embodiments, the nanosheets 122 can be interchangeably referred to as nanowires, nanoslabs and nanorings, depending on their geometry. For example, in some other embodiments, the channel layers 122 may be trimmed to have a substantial rounded shape (i.e., cylindrical) due to the selective etching process for completely removing the sacrificial layers 121 (referring to FIG. 5B). In that case, the resultant channel layers 122 can be called nanowires.

In some embodiments, the sacrificial layers 121 (referring to FIG. 5B) are SiGe and the channel layers 122 are silicon allowing for the selective removal of the sacrificial layers 121 (referring to FIG. 5B). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ is removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 121 (referring to FIG. 5B) are removed. Moreover, because oxidation rate of Si is much lower (sometimes 30 times lower) than oxidation rate of SiGe, the channel layers 122 may remain substantially intact during the channel release process.

Reference is made to FIGS. 7A through 7C. Replacement gate structures 220 are formed in the gate trench GT to respectively surround each of the nanosheets 122 suspended in the gate trench GT. The gate structures 220 may be final gates of GAA FETs. The final gate structures may be a high-k/metal gate stack, however other compositions are possible. In some embodiments, the gate structure 220 forms the gate associated with the multi-channels provided by the plurality of nanosheets 122. For example, the high-k/metal gate structure 220 is formed within the openings/spaces O1 provided by the release of nanosheets 122. The high-k/metal gate structures 220 may be between the channel layers 122 and surrounded by the inner spacers 160. The high-k/metal gate structures 220 may include gate dielectric layers 222 formed around the nanosheets 122 and gate metal layer 224 over the gate dielectric layers 222. After the gate metal layers 224 are formed, a planarization processes (e.g., chemical mechanical polish process) may be performed to remove excessive gate materials, resulting in the high-k/metal gate structures 220 having top surfaces level with top surfaces of the CESL 210 and the ILD layer 211.

In some embodiments, the gate dielectric layer 222 may include an interfacial layer and a high-k gate dielectric layer over the interfacial layer. In some embodiments, the interfacial layer is silicon oxide formed on exposed surfaces of semiconductor materials in the gate trenches GT by using, for example, thermal oxidation, chemical oxidation, wet oxidation or the like. As a result, surface portions of the layers 122 and the substrate portion 112 exposed in the gate trenches GT are oxidized into silicon oxide to form interfacial layer of the gate dielectric layer 222. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO; HZO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

After forming the gate dielectric layers 222, the gate metal layer 224 may be formed over the gate dielectric layers 222. As illustrated in FIGS. 7A through 7C, the gate metal layer 224 may be fill metal filling up a remainder of gate trenches GT. In some embodiments, the gate metal layer 224 may include exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable conductive materials, and the gate metal layers 224 may be served as gate electrode layers.

As illustrated in FIGS. 7A and 7B, the formed high-k/metal gate structures 220 may include outer gate portions above the topmost channel layers 122 and with a height MGH1. The formed high-k/metal gate structures 220 may include inner gate portions between the channel layers 122 and between the bottommost channel layers 122 and the substrate portions 112, and the inner gate portions of the high-k/metal gate structures 220 may have height MGH2, MGH3 or MGH4 from top to bottom. In FIGS. 7A and 7B, the height MGH1 of the outer gate portions of the gate structures 220 is greater than each of the heights MGH2, MGH3 and MGH4 of the inner gate portions of the gate structures 220.

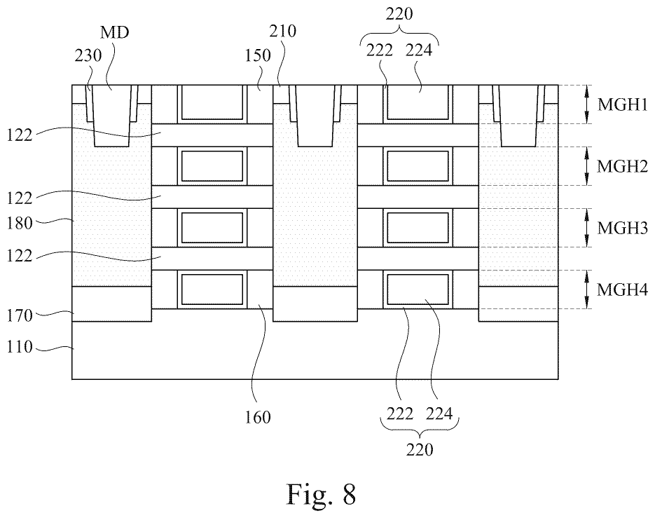

Reference is made to FIG. 8. Source/drain contacts MD are formed for providing electrical connection to the source/drain epitaxial structures 180. The formation of the source/drain contact MD includes etching source/drain contact openings in the CESL 210 and the ILD layer 211 to expose a front-side of the source/drain epitaxial structure 180, and depositing one or more conductive materials into the source/drain contact openings, followed by a planarization process (e.g., CMP process) to remove an excess portion of the conductive material outside the source/drain contact openings. The conductive materials may include TiN, TaN, W, Co, Ru, Al, Cu, other metals, the like, or the combination thereof. A remaining portion of the conductive material forms the source/drain contact MD.

After the planarization process, the high-k/metal gate structures 220 are exposed. In some embodiments, the planarization process following the deposition of the conductive materials into the source/drain contact opening may also remove a portion of the high-k/metal gate structure 220. Thus, the height MGH1 of the high-k/metal gate structures 220 over the topmost channel layers 122 is reduced by the planarization process.

In one or more embodiments of the present disclosure, by controlling the end point of the planarization process to remove excessive gate materials after the formation of the high-k/metal gate structures 220 and by controlling the end point of the planarization process following the deposition of the conductive materials into the source/drain contact openings, the height MGH1 of the high-k/metal gate structure 220 above the topmost channel layer 122 may be substantially equal to or less than at least one of the heights MGH2, MGH3 and MGH4. In some embodiments, the heights MGH2, MGH3 and MGH4 are the same. In some embodiments, the heights MGH2, MGH3 and MGH4 are different from each other. In some embodiments, the height MGH1 is less than any of the heights MGH2, MGH3 and MGH4. In some embodiments, the height MGH1 is in a range from about 5 nm to about 20 nm. In some embodiments, each of the heights MGH2, MGH3 and MGH4 is in a range from about 4 nm to about 18 nm. In some embodiment, a height difference between the height MGH1 and one of the heights MGH2, MGH3 and MGH4 is in a range from about numbers of angstroms to about 10 nm.

In some embodiments, after etching the source/drain contact openings in the CESL 210 and the ILD layer 211, and prior to depositing the conductive materials into the source/drain contact openings, a metal alloy layer is formed on a portion of the source/drain epitaxial structures 180 exposed by the source/drain contact openings. The metal alloy layer may be a silicide layer formed by a silicide (salicide) process. The silicide process converts a surface portion of the source/drain epitaxial structure 180 into the silicide contacts. Silicide processing involves deposition of a metal that undergoes a silicidation reaction with silicon (Si). In order to form silicide contacts on the source/drain epitaxial structure 180, a metal material is blanket deposited on the exposed front-side of the source/drain epitaxial structure 180. After heating the wafer to a temperature at which the metal reacts with the silicon of the source/drain epitaxial structure 180 to form contacts, unreacted metal is removed. The silicide contacts remain over the front-side of the source/drain epitaxial structure 180, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layer may include germanium.

As illustrated in FIG. 8, in some embodiments, after etching the source/drain contact opening in the CESL 210 and the ILD layer 211, and prior to depositing the conductive materials into the source/drain contact openings, barrier layers 230 are formed. In FIG. 8, the barrier layers 230 are formed on opposite sidewalls of the source/drain contact openings in which the source/drain contacts MD are formed in. In some embodiments, formation of the barrier layers 230 includes depositing the barrier layers 230 in the source/drain contact opening, etching bottom portions of the deposited the barrier layers 230 until the source/drain epitaxial structure 180 is recessed, followed by depositing conductive material of the source/drain contacts MD over the barrier layers 230 and the recessed regions of the source/drain epitaxial structures 180. In some embodiments, the planarization process to remove an excess portion of the conductive material of the source/drain contacts MD outside the source/drain contact openings may be performed on the barrier layers 230, and the top surfaces of the barrier layers 230 may be level with top surfaces of the source/drain contacts MD. In some embodiments, the barrier layers 230 include dielectric material such as oxide or nitride, or conductive material such as TiN or TaN.

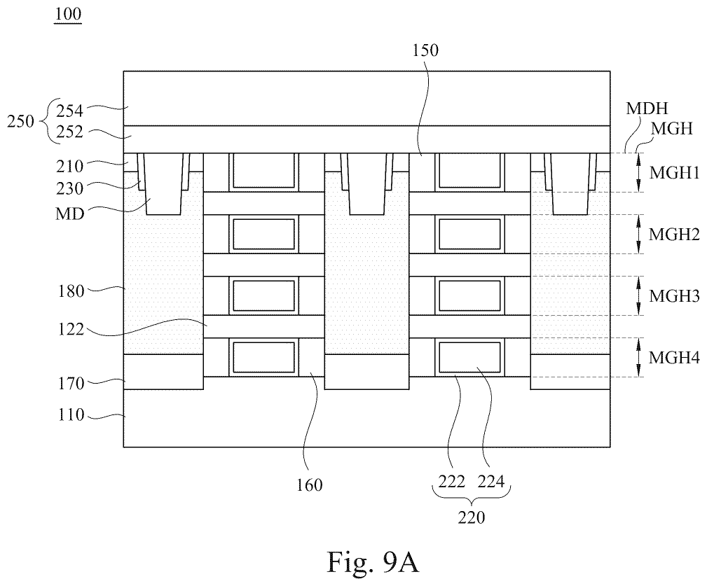

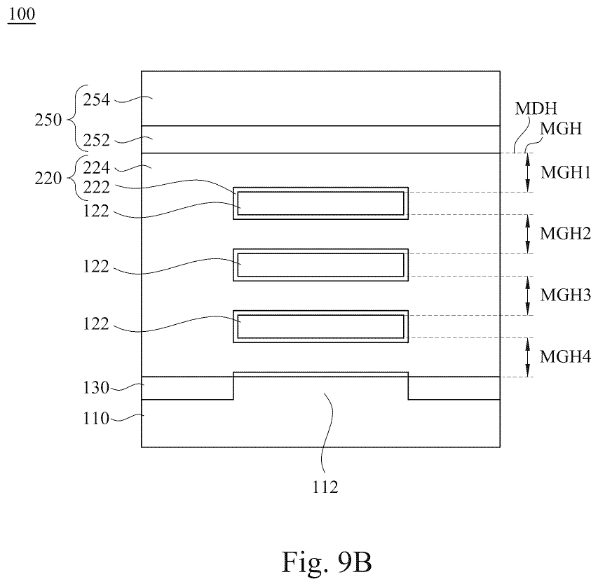

Reference is made to FIGS. 9A and 9B. A dielectric material 250 is formed over the source/drain contact MD and the high-k/metal gate structure 220. The dielectric material 250 may include an etch stop layer (ESL) 252 and an ILD layer 254 over the etch stop layer 252. In some examples, the etch stop layer 252 includes a silicon nitride layer, silicon oxide layer, a silicon oxynitride layer, and/or other suitable. The ILD layer 254 is then deposited over the etch stop layer 252. In some embodiments, the ILD layer 254 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the etch stop layer 252. The ILD layer 254 may be deposited by a CVD process or other suitable deposition technique. A semiconductor device 100 is formed as illustrated in FIGS. 9A and 9B.

In some embodiments, a front-side multilayer interconnection (MLI) structure may be formed over the dielectric material 250. The front-side MLI structure may include a plurality of front-side metallization layers. The number of front-side metallization layers may vary according to design specifications of the integrated circuit. The front-side metallization layers each comprise a front-side inter-metal dielectric (IMD) layer, one or more horizontal interconnects, such as front-side metal lines, respectively extending horizontally or laterally in the front-side IMD layer, and vertical interconnects, such as front-side conductive vias, respectively extending vertically in the front-side IMD layer.

In some embodiments, laterally overlapping areas of the source/drain contacts MD and the outer gate portions of the high-k/metal gate structures 220 may cause effective parasitic capacitances. According to one or more embodiments of the present disclosure, in the semiconductor device 100 as illustrated in FIGS. 9A and 9B, by reducing the height MGH1 of the outer gate portions of the high-k/metal gate structures 220, the laterally overlapping areas of the source/drain contacts MD and the outer gate portions of the high-k/metal gate structures 220 may be reduced, and the parasitic capacitances caused by the source/drain contacts MD and the high-k/metal gate structures 220 can be reduced. In some embodiments, dielectric material between the source/drain contacts MD and the outer gate portions of the high-k/metal gate structures 220 such as the barrier layers 230 can be low-k dielectric material to further reduce the effective parasitic capacitances caused by the source/drain contacts MD and the high-k/metal gate structures 220.

As illustrated in FIGS. 9A and 9B, the topmost surfaces of the gate metal layers 224 of the high-k/metal gate structures 220 are located at an elevation MGH. The topmost surfaces of the source/drain contacts MD are located at an elevation MDH. In some embodiments, as illustrated in FIGS. 9A and 9B, the elevation MGH of the topmost surfaces of the high-k/metal gate structures 220 is substantially level with the elevation MDH of the topmost surfaces of the source/drain contacts MD.

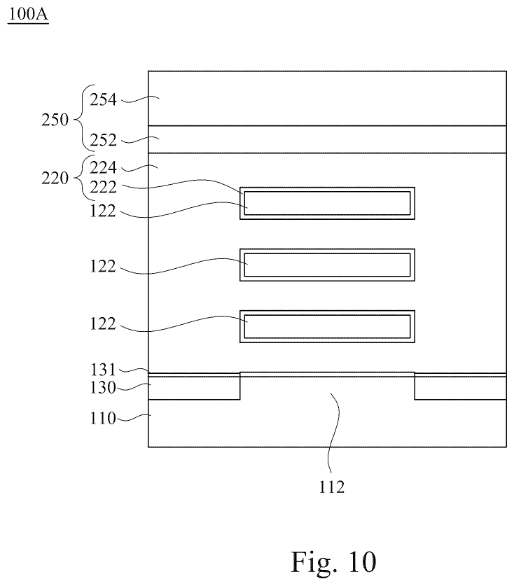

Reference is made to FIG. 10. FIG. 10 is a cross-sectional view of a semiconductor device 100A in accordance with some embodiments of the present disclosure. FIG. 10 illustrates a cross-sectional view of the semiconductor device 100A along one of the high-k/metal gate structures 220. Details of the present embodiments are similar to those illustrated in FIGS. 1-9B.

The height MGH1 of the high-k/metal gate structure 220 above the topmost channel layer 122 may be substantially equal to or less than at least one of the heights MGH2, MGH3 and MGH4. As illustrated in FIGS. 9B and 10, a difference between the semiconductor device 100 and the semiconductor device 100A may include that the semiconductor device 100A further includes protection hard masks 131 over the isolation structures 130. The protection hard masks 131 may be used to protect the isolation structures 130 during forming the gate trenches GT (referring to FIGS. 6A-6C). In some embodiments, the protection hard masks 131 may include single layer or multiple layers of SiN, SiO₂, SiON, SiCN, SiCON, SiCO, high-k material such as HfO or AlO, a combination thereof and/or other appropriate semiconductor materials.

Reference is made to FIG. 11. FIG. 11 is a cross-sectional view of a semiconductor device 100B in accordance with some embodiments of the present disclosure. FIG. 11 illustrates a cross-sectional view of the semiconductor device 100B along the channel layers 122. Details of the present embodiments are similar to those illustrated in FIGS. 1-9B.

The height MGH1 of the high-k/metal gate structure 220 above the topmost channel layer 122 may be substantially equal to or less than at least one of the heights MGH2, MGH3 and MGH4. As illustrated in FIGS. 9A and 11, a difference between the semiconductor device 100 and the semiconductor device 100B may include that the semiconductor device 100B further includes a middle etch stop layer 240 over the high-k/metal gate structure 220. In some embodiments, after the formation and planarization of the high-k/metal gate structures 220 (referring to FIGS. 7A-8) and prior to the formation of the source/drain contact MD (referring to FIG. 8), the middle etch stop layer 240 may deposited over the dielectric material including the CESL 210 and the ILD layer 211 and the high-k/metal gate structures 220. The middle etch stop layer 240 may include one or more suitable dielectric materials, such as silicon oxide, silicon nitride, the like, or the combination thereof. In some embodiments, the planarization of the source/drain contact MD may stop at the middle etch stop layer 240. The source/drain contacts MD and the barrier layers 230 near the source/drain contacts MD may then be formed through the middle etch stop layer 240. The middle etch stop layer 240 may be used to protect the high-k/metal gate structures 220 during formation of the source/drain contacts MD. As illustrated in FIG. 11, the elevation MDH of the topmost surfaces of the source/drain contacts MD is higher than the elevation MGH of the topmost surfaces of the high-k/metal gate structures 220.

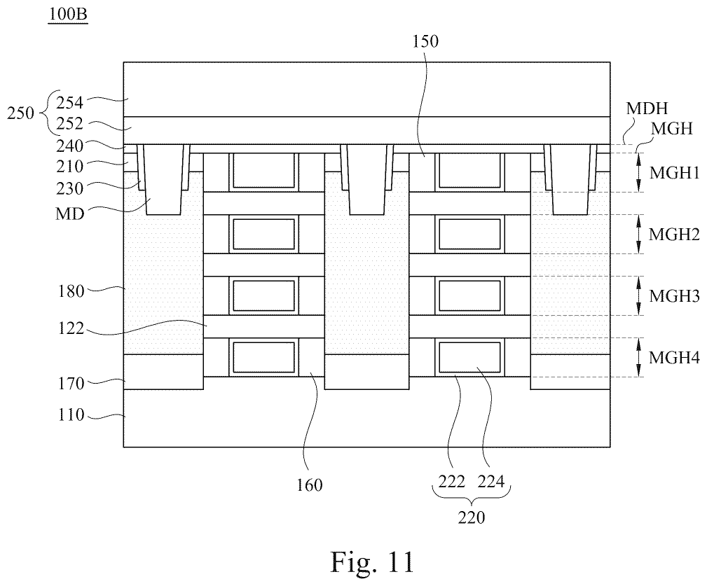

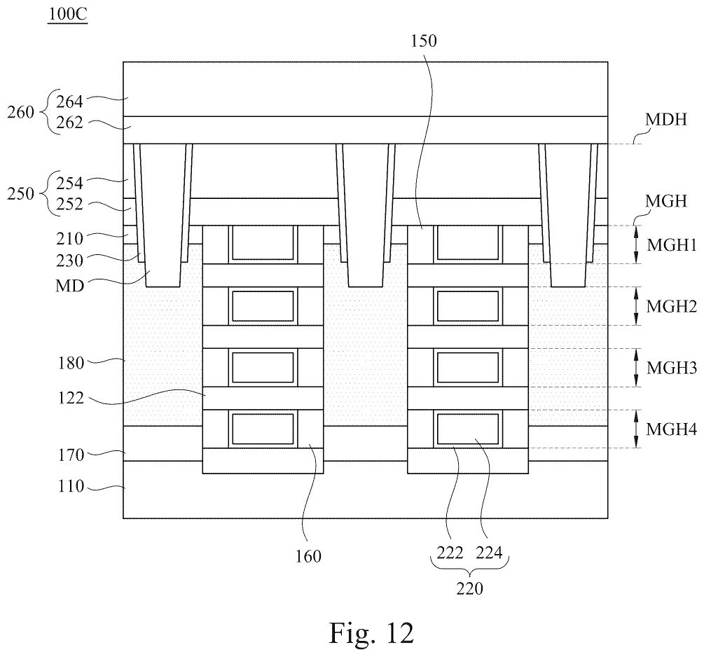

Reference is made to FIG. 12. FIG. 12 is a cross-sectional view of a semiconductor device 100C in accordance with some embodiments of the present disclosure. FIG. 12 is a cross-sectional view of a semiconductor device 100C along the channel layers 122. Details of the present embodiments are similar to those illustrated in FIGS. 1-9B.

In FIG. 12, the height MGH1 of the high-k/metal gate structure 220 above the topmost channel layer 122 may be substantially equal to or less than at least one of the heights MGH2, MGH3 and MGH4. As illustrated in FIGS. 9A and 12, the semiconductor device 100C may be substantially the same as the semiconductor device 100, except that the semiconductor device 100C includes a dielectric material 260 over the dielectric material 250. In FIG. 12, the dielectric material 260 includes an ESL 262 over the ILD layer 254 of the dielectric material 250 and an ILD layer 264 over the ESL 262. A difference between the semiconductor device 100 and the semiconductor device 100C may further include that the source/drain contacts MD and the barrier layers 230 extend from a top surface of the ILD layer 254. As illustrated in FIG. 12, the elevation MDH of the top surfaces of the source/drain contacts MD is higher than the elevation MGH of the top surfaces of the high-k/metal gate structures 220.

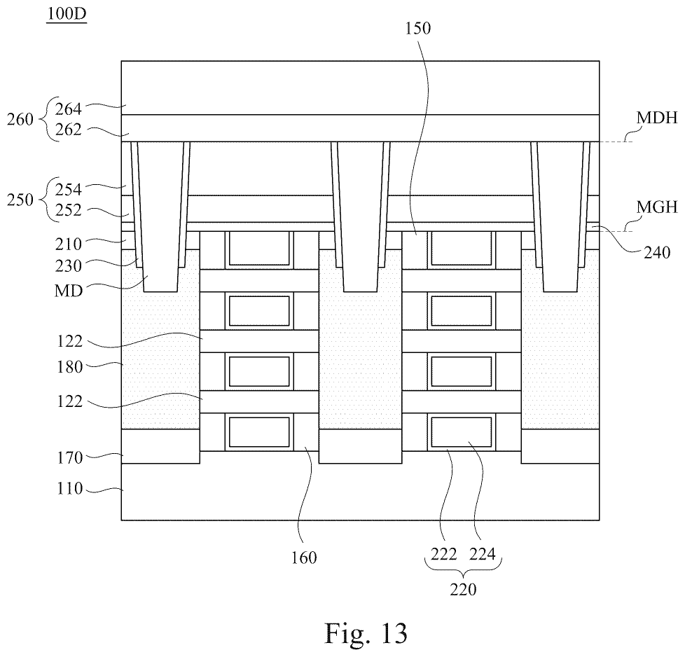

Reference is made to FIG. 13. FIG. 13 is a cross-sectional view of a semiconductor device 100D in accordance with some embodiments of the present disclosure. FIG. 13 is a cross-sectional view of a semiconductor device 100C along the channel layers 122. As illustrated in FIGS. 12 and 13. the semiconductor device 100D is substantially the same as the semiconductor device 100C, except that the semiconductor device 100D further includes a middle etch stop layer 240 over the high-k/metal gate structure 220 and the source/drain contacts MD and the barrier layers 230 are formed through the middle etch stop layer 240. Details of the present embodiments are similar to those illustrated in FIGS. 1-9B and 11. In FIG. 13, the elevation MDH of topmost surfaces of the source/drain contacts MD is higher than the middle etch stop layer 240.

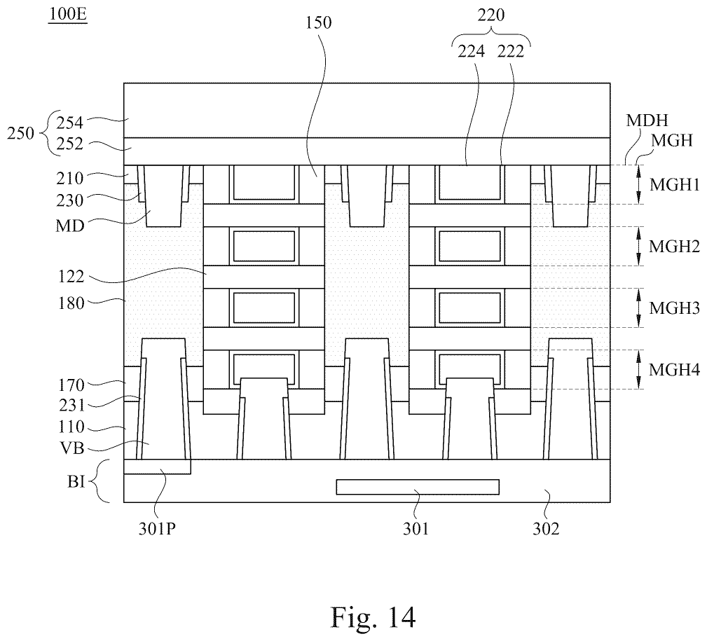

Reference is made to FIG. 14. FIG. 14 is a cross-sectional view of a semiconductor device 100E in accordance with some embodiments of the present disclosure. FIG. 14 is a cross-sectional view of a semiconductor device 100E along the channel layers 122. In FIG. 14, the height MGH1 of the high-k/metal gate structure 220 above the topmost channel layer 122 may be substantially equal to or less than at least one of the heights MGH2, MGH3 and MGH4. As illustrated in FIGS. 9A and 14, the semiconductor device 100E is substantially the same as the semiconductor device 100, except that the semiconductor device 100E includes backside source/drain contacts VB.

In some embodiments, the backside source/drain contacts VB may be formed for providing electrical connection to the source/drain epitaxial structure 180. The formation of the backside source/drain contact VB includes etching backside source/drain contact openings in the substrate 110 and the bottom isolation layer 170 to expose a backside of the source/drain epitaxial structure 180, and depositing one or more conductive materials into the backside source/drain contact opening, followed by a planarization process on a backside of the substrate 110 to remove an excess portion of the conductive material outside the backside source/drain contact opening. In some embodiments, the conductive materials may include TiN, TaN, W, Co, Ru, Al, Cu, other metals, the like, or the combination thereof. A remaining portion of the conductive material forms the backside source/drain contact. In some embodiments, the etching backside source/drain contact openings may extend into the source/drain epitaxial structure 180.

In some embodiments, prior to forming the backside source/drain contact openings in the substrate 110 and the bottom isolation layer 170, a thickness of the substrate 110 can be reduced by performing suitable thinning process on the backside of the substrate 110. In some embodiments, the after etching the backside source/drain contact opening in the substrate 110 and the bottom isolation layer 170, and prior to depositing the conductive materials of the backside source/drain contacts VB into the backside source/drain contact opening, barrier layers 231 may be formed on opposite sidewalls of the backside source/drain contact opening in the substrate 110 and the bottom isolation layer 170. In FIG. 14, the backside source/drain contacts VB and the barrier layers 231 extend into the source/drain epitaxial structure 180. Details of formation of the barrier layers 231 may be similar to formation of the barrier layer 230 as illustrated in FIG. 8. In some embodiments, the barrier layers 231 include dielectric material such as oxide or nitride, or conductive material such as TiN or TaN.

In some embodiments, after etching the backside source/drain contact opening in the substrate 110 and the bottom isolation layer 170, and prior to depositing the conductive materials into the backside source/drain contact opening, a metal alloy layer is formed on a portion of the source/drain epitaxial structures 180 exposed by the backside source/drain contact opening. The metal alloy layer may be a silicide layer formed by a silicide (salicide) process. The silicide process converts a backside surface portion of the source/drain epitaxial structure 180 into the silicide contacts. Silicide processing involves deposition of a metal that undergoes a silicidation reaction with silicon (Si). In order to form silicide contacts on the source/drain epitaxial structure 180, a metal material is blanket deposited on the exposed backside of the source/drain epitaxial structure 180. After heating the wafer to a temperature at which the metal reacts with the silicon of the source/drain epitaxial structure 180 to form contacts, unreacted metal is removed. The silicide contacts remain over the backside of the source/drain epitaxial structure 180, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layer may include germanium.

In some embodiments, a backside multilayer interconnection (MLI) structure BI may be formed over the backside of the backside source/drain contacts VB. The backside MLI structure may include a plurality of backside metallization layers. The number of backside metallization layers may vary according to design specifications of the integrated circuit. The backside metallization layers each comprise a backside inter-metal dielectric (IMD) layer 302, one or more horizontal interconnects, such as backside metal lines 301, respectively extending horizontally or laterally in the backside IMD layer 302, and vertical interconnects, such as backside conductive vias, respectively extending vertically in the backside IMD layer.

In some embodiments, as illustrated in FIG. 14, the backside metal lines 301 in the backside metallization layers of the backside MLI structure BI may include a backside power rail 301P. In FIG. 14, the backside power rail 301P is connected to one of the source/drain epitaxial structures 180 through the backside source/drain contacts VB, so as to provide a routing space for the semiconductor device 100E from the backside of the substrate 110. In some embodiments, the backside power rail 301P may be referred as a super power rail (SPR).

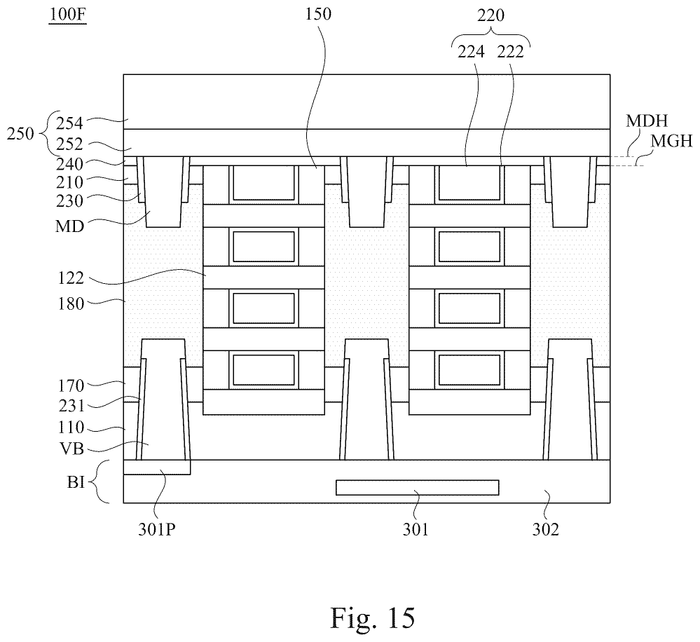

Reference is made to FIG. 15. FIG. 15 is a cross-sectional view of a semiconductor device 100F in accordance with some embodiments of the present disclosure. FIG. 15 is a cross-sectional view of a semiconductor device 100F along the channel layers 122. As illustrated in FIGS. 14 and 15. the semiconductor device 100F is substantially the same as the semiconductor device, except that the semiconductor device 100F further includes a middle etch stop layer 240 over the high-k/metal gate structure 220 and the source/drain contacts MD and the barrier layers 230 are formed through the middle etch stop layer 240. Details of the present embodiments are similar to those illustrated in FIGS. 1-9B and 11. In FIG. 15, the elevation MDH of the source/drain contacts MD is higher than the middle etch stop layer 240, and the elevation MDH of the source/drain contacts MD is higher than the elevation MGH of the topmost surfaces of the high-k/metal gate structures 220.

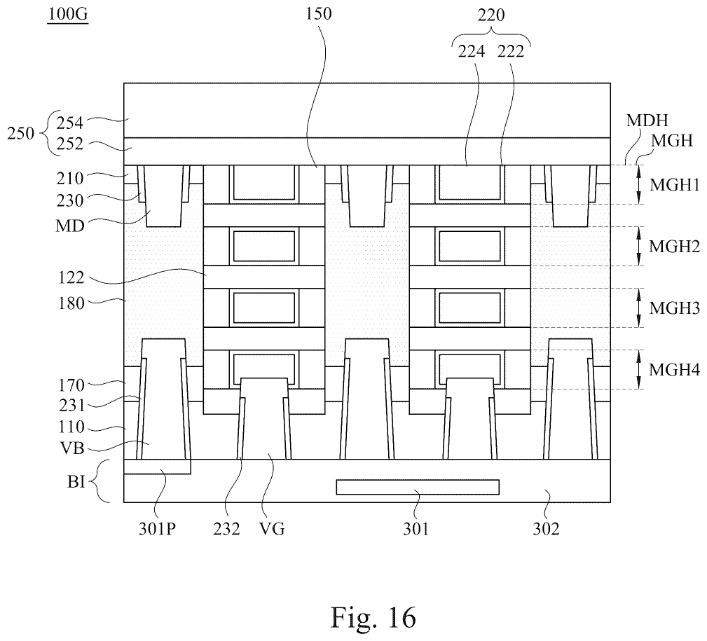

Reference is made to FIG. 16. FIG. 16 is a cross-sectional view of a semiconductor device 100G in accordance with some embodiments of the present disclosure. FIG. 16 is a cross-sectional view of a semiconductor device 100G along the channel layers 122.

In FIG. 16, the height MGH1 of the high-k/metal gate structure 220 above the topmost channel layer 122 may be substantially equal to or less than at least one of the heights MGH2, MGH3 and MGH4. As illustrated in FIGS. 14 and 16, a difference between the semiconductor device 100E and the semiconductor device 100G may include that the semiconductor device 100G includes backside gate contacts VG. In some embodiments, the backside gate contacts VG may be formed during forming the backside source/drain contacts VB. For example, formation of the backside gate contacts VG may include forming backside gate contact openings through the substrate 110 and the gate dielectric layers 222 to the gate metal layers 224 of the high-k/metal gate structures 220 below the bottommost channel layers 122 and depositing conductive material in the backside gate contact openings. In some embodiments, prior to depositing the conductive material in the backside gate contact openings, barrier layers 232 may be formed in the opposite sidewalls of the backside gate contact openings. Details of formation of the barrier layers 232 may be similar to formation of the barrier layer 230 as illustrated in FIG. 8. In some embodiments, the barrier layers 232 include dielectric material such as oxide or nitride, or conductive material such as TiN or TaN.

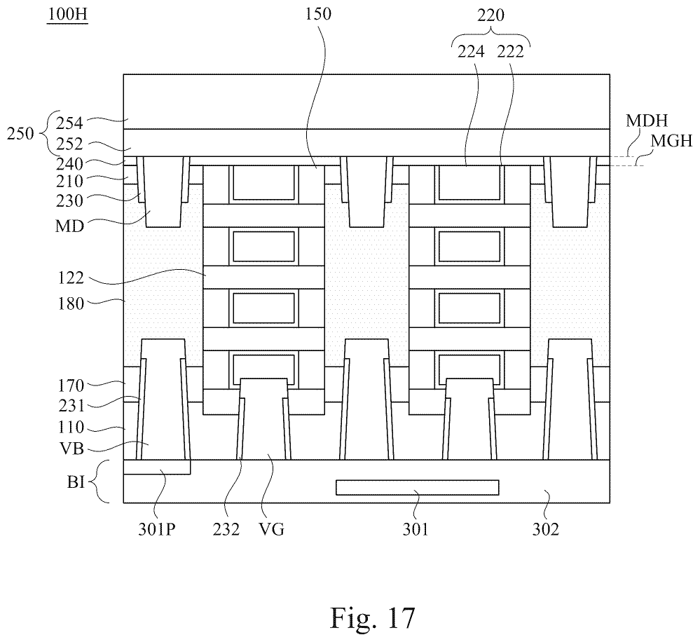

Reference is made to FIG. 17. FIG. 17 is a cross-sectional view of a semiconductor device 100H in accordance with some embodiments of the present disclosure. FIG. 17 is a cross-sectional view of a semiconductor device 100H along the channel layers 122. As illustrated in FIGS. 16 and 17. the semiconductor device 100H is substantially the same as the semiconductor device 100G, except that the semiconductor device 100H further includes a middle etch stop layer 240 over the high-k/metal gate structure 220 and the source/drain contacts MD and the barrier layers 230 are formed through the middle etch stop layer 240. Details of the present embodiments are similar to those illustrated in FIGS. 1-9B and 11. In FIG. 17, the elevation MDH of the source/drain contacts MD is higher than the middle etch stop layer 240, and the elevation MDH of the source/drain contacts MD is higher than the elevation MGH of the topmost surfaces of the high-k/metal gate structures 220.

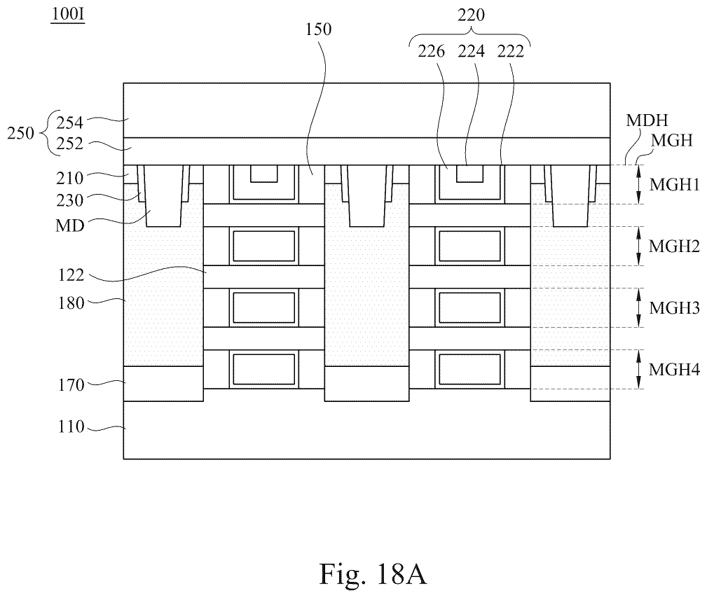

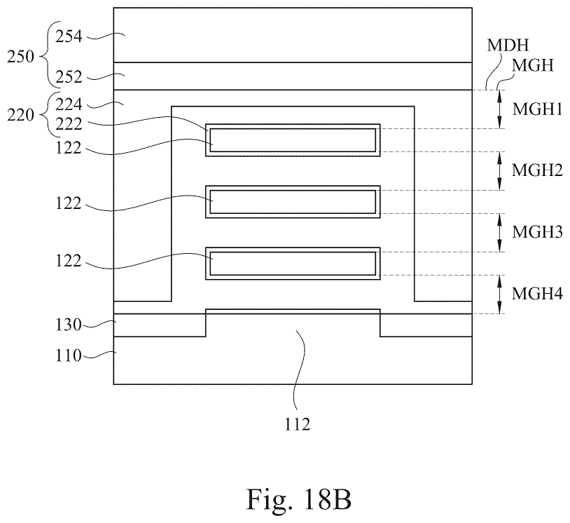

Reference is made to FIGS. 18A and 18B. FIGS. 18A and 18B are cross-sectional views of a semiconductor device 100I in accordance with some embodiments of the present disclosure. FIG. 18A is a cross-sectional view of a semiconductor device 100I along the channel layers 122. FIG. 18B is a cross-sectional view of a semiconductor device 100I along one of the high-k/metal gate structures 220.

In FIGS. 18A and 18B, the height MGH1 of the high-k/metal gate structure 220 above the topmost channel layer 122 may be substantially equal to or less than at least one of the heights MGH2, MGH3 and MGH4. As illustrated in FIGS. 9A and 18A, a difference between the semiconductor device 100 and the semiconductor device 100I may include that the high-k/metal gate structures 220 further include work function metal stacks 226 between the gate dielectric layers 222 and the gate metal layers 224.

In some embodiments, each of the work function metal stacks 226 may include one or more work function metal layers stacked one over another. The one or more work function metal layers in the gate metal layer 224 provide a suitable work function for the high-k/metal gate structures 220. For an n-type GAA FET, the work function metal stacks 226 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the work function metal stacks 226 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

Reference is made to FIG. 19. FIG. 19 is a cross-sectional view of a semiconductor device 100J in accordance with some embodiments of the present disclosure. FIG. 19 is a cross-sectional view of a semiconductor device 100J along the channel layers 122. As illustrated in FIGS. 18A and 19. the semiconductor device 100J is substantially the same as the semiconductor device 100I, except that the semiconductor device 100J further includes a middle etch stop layer 240 over the high-k/metal gate structure 220 and the source/drain contacts MD and the barrier layers 230 are formed through the middle etch stop layer 240. Details of the present embodiments are similar to those illustrated in FIGS. 1-9B and 11. In FIG. 19, the elevation MDH of the source/drain contacts MD is higher than the middle etch stop layer 240, and the elevation MDH of the source/drain contacts MD is higher than the elevation MGH of the topmost surfaces of the high-k/metal gate structures 220.

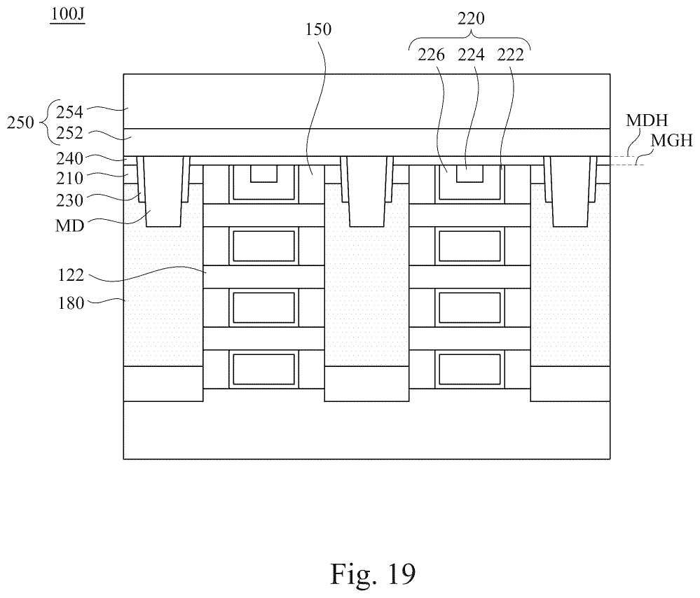

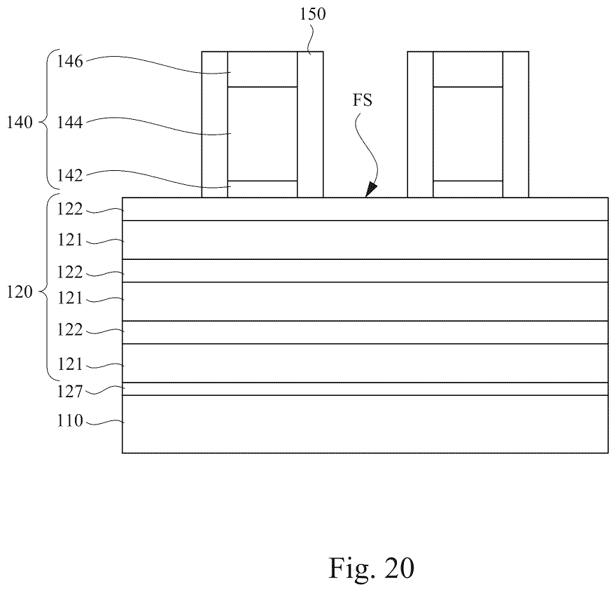

FIGS. 20-22 illustrate schematic views of intermediate stages in the manufacture of a semiconductor device 100K in accordance with some embodiments of the present disclosure.

Reference is made to FIG. 20. A bottom sacrificial layer 127 is formed over a substrate 110. An epitaxial stack 120 is formed over a bottom sacrificial layer 127. The epitaxial stack 120 may include sacrificial layers 121 and channel layers 122 alternatively arranged with each other.

In some embodiments, the layers 121, 122 and 127 may include SiGe with various semiconductor compositions based on providing differing oxidation and/or etching selectivity properties. For example, the channel layers 122 are SiₓGe₁₋ₓ, the sacrificial layers 121 are Si_{y}Ge_{1-y}, and the sacrificial layer 127 is Si_{z}Ge_{1-z}, in which x, y, and z are in a range from 0 to 1, x>y>z. In some embodiments, w is in a range from about 0.35 to about 0.45. However, other embodiments are possible including those that provide for the material/compositions having different oxidation rates and/or etch selectivity. In some embodiments, the Si oxidation rate of the channel layers 122 is less than the SiGe oxidation rate of the sacrificial layers 121, and the SiGe oxidation rate of the sacrificial layers 121 is less than the SiGe oxidation rates of the sacrificial layers 127. In some embodiments, the layers 121, 122 and 127 are intrinsic semiconductor layers, which are not intentionally doped, for example, not having intentionally placed dopants, but rather having a doping resulting from process contaminants. In some embodiments, the layers 121, 122 and 127 are substantially dopant-free (i.e., having an extrinsic dopant concentration from about 0 cm⁻³ to about 1×10¹⁸ cm⁻³), where for example, no intentional doping is performed during the epitaxial growth process. Other details of the layers 121, 122 and 127 of the epitaxial stack 120 are similar to those illustrated above, and therefore not repeated above.

After the formation of the epitaxial stack 120, the epitaxial stack 120 may be patterned into fins FS, and then dummy gate structures 140 are formed on the epitaxial stack 120. Gate spacers 150 are formed on opposite sidewalls of the dummy gate structures 140.

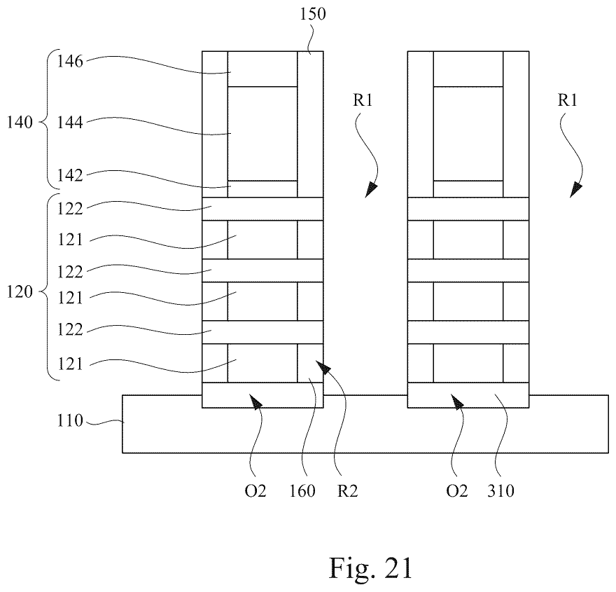

Reference is made to FIG. 21. Exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS. The recesses R1 may extend through the epitaxial layers 121, 122 and 127. After the anisotropic etching, end surfaces of the epitaxial layers 121, 122 and 127 are exposed and aligned with respective outermost sidewalls of the gate spacers 150, due to the anisotropic etching. Then, the sacrificial layers 127 as illustrated in FIG. 20 may be replaced with isolation layers 310. For example, the sacrificial layer 127 are removed by using suitable selective etching process resulting in an opening/space O2 between the epitaxial stack 120 and the substrate 110. In some embodiments, the etching process may also trims portions of the substrate 110 below the sacrificial layer 127, such that openings O2 may extend into the substrate 110, as illustrated in FIG. 21. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. Thus, the layers 121 and 122 may have a higher etch resistance to the selective etching process than that of the sacrificial layer 127. The isolation layers 310 are then formed in the opening/space O2, as illustrated in FIG. 21. In some embodiments, the isolation layer 310 may include a dielectric material, such as SiN, SiO₂, SiON, SiCN, SiCON, SiCO, high-k dielectrics (e.g., HfO, AlO, etc.), other low-k dielectric materials, the like, or the combination thereof. The isolation layers 310 may be a single-layer or a multi-layer structure. Formation of the isolation layers 310 may include depositing a dielectric material layer into the opening/spaces O2, followed by an anisotropic etching process to trim the deposited dielectric material layer. Through the anisotropic etching process, only portions of the deposited dielectric material layer that fill the opening/spaces O2 are left.

In FIG. 21, the sacrificial layers 121 are laterally or horizontally recessed by using suitable selective etching process, resulting in lateral/sidewall recesses R2 vertically between corresponding channel layers 122. Inner spacers 160 are formed in the recesses R2. Formation of the inner spacers 160 may include depositing an inner spacer material layer, followed by an anisotropic etching process to trim the deposited inner spacer material layer. Through the anisotropic etching process, only portions of the deposited inner spacer material layer that fill the lateral/sidewall recesses R2 are left.

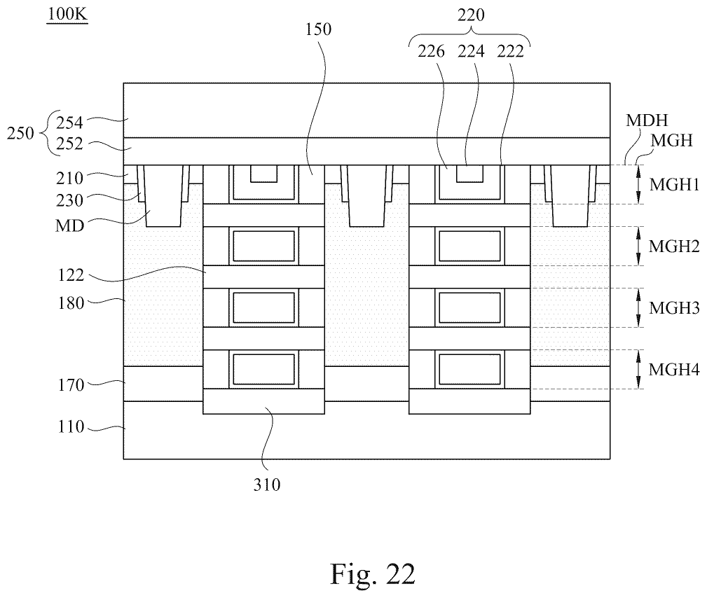

Reference is made to FIG. 22. The bottom isolation layers 170, the source/drain epitaxial structures 180 and the dielectric material including contact etch stop layers (CESLs) 210 and ILD layers 211 are formed in the recess R1 in a sequence. The dummy gate structure 140 and the sacrificial layer 121 are replaced with high-k/metal gate structures 220. The high-k/metal gate structures 220 surround the channel layers 122. In FIG. 22, the high-k/metal gate structures 220 may include gate dielectric layers 222, work function metal stacks 226 over the gate dielectric layers 222 and the gate metal layers over the work function metal stacks 226. After formation of the high-k/metal gate structures 220, a planarization processes (e.g., chemical mechanical polish process) may be performed to remove excessive gate materials of the high-k/metal gate structures 220. The planarized high-k/metal gate structures 220 may have outer gate portions over the topmost channel layer 122 and inner gate portions between the channel layers 122. The outer gate portions of the planarized high-k/metal gate structures 220 may have a height MGH1 substantially equal to or less than one of the heights MGH2, MGH3 and MGH4 of the inner gate portions of high-k/metal gate structures 220. After the high-k/metal gate structures 220 are formed, the source/drain contacts MD, the barrier layers 230 and the dielectric material 250 including the ESL 252 and the ILD layer 254 may formed, and the semiconductor device 100K is provided. Other details of the present embodiments are similar to those illustrated above, and therefore not repeated herein. FIG. 22 illustrates a cross-sectional view of the semiconductor device 100K along the channel layers 122 in accordance with some embodiments of the present disclosure.

In FIG. 22, the height MGH1 of the high-k/metal gate structure 220 above the topmost channel layer 122 may be substantially equal to or less than at least one of the heights MGH2, MGH3 and MGH4. As illustrated in FIGS. 18A and 22, a difference between the semiconductor device 100I and the semiconductor device 100K may include that the semiconductor device 100K includes the isolation layers 310 between the bottommost inner gate portions of the high-k/metal gate structures 220 and the substrate 110.

Reference is made to FIG. 23. FIG. 23 is a cross-sectional view of a semiconductor device 100M in accordance with some embodiments of the present disclosure. FIG. 23 is a cross-sectional view of a semiconductor device 100M along the channel layers 122. As illustrated in FIGS. 22 and 23, the semiconductor device 100M is substantially the same as the semiconductor device 100K, except that the semiconductor device 100M further includes a middle etch stop layer 240 over the high-k/metal gate structure 220 and the source/drain contacts MD and the barrier layers 230 are formed through the middle etch stop layer 240. Details of the present embodiments are similar to those illustrated in FIGS. 1-9B and 11. In FIG. 23, the elevation MDH of the source/drain contacts MD is higher than the middle etch stop layer 240, and the elevation MDH of the source/drain contacts MD is higher than the elevation MGH of the topmost surfaces of the high-k/metal gate structures 220.

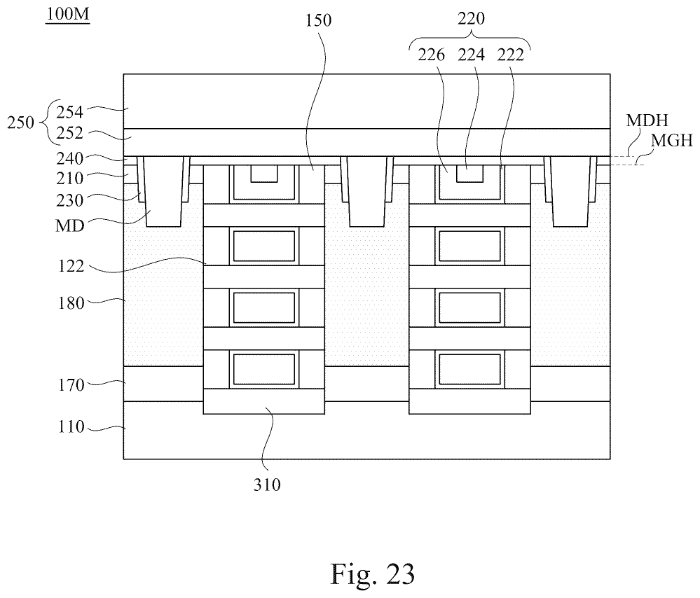

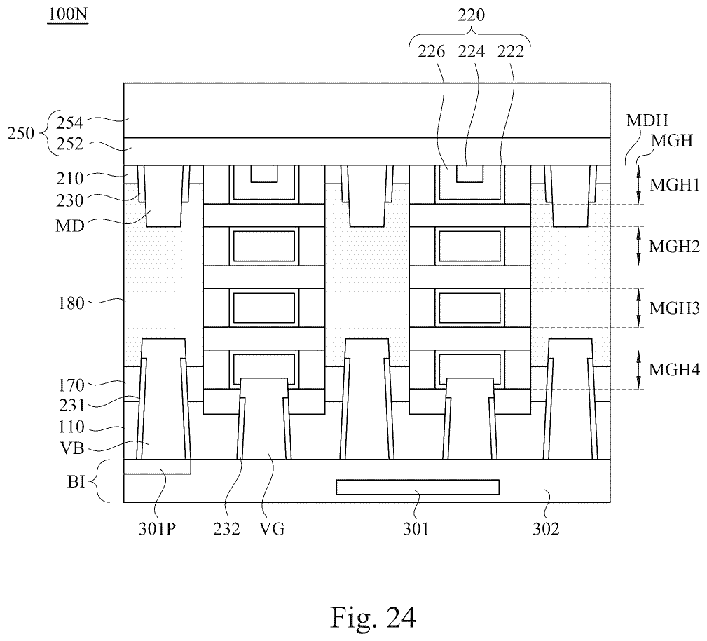

Reference is made to FIG. 24. FIG. 24 is a cross-sectional view of a semiconductor device 100N in accordance with some embodiments of the present disclosure. FIG. 24 is a cross-sectional view of a semiconductor device 100N along the channel layers 122. In FIG. 24, the height MGH1 of the high-k/metal gate structure 220 above the topmost channel layer 122 may be substantially equal to or less than at least one of the heights MGH2, MGH3 and MGH4.

As illustrated in FIGS. 22 and 24, the semiconductor device 100N is substantially the same as the semiconductor device 100K, except that the semiconductor device 100N includes backside source/drain contacts VB with barrier layers 231 and backside gate contacts VG with barrier layers 232. A difference between the semiconductor device 100K and the semiconductor device 100N may include that the semiconductor device 100N includes a backside multilayer interconnection (MLI) structure BI may be formed over the backside of the backside source/drain contacts VB. The backside MLI structure may include a plurality of backside metallization layers with backside metal lines 301 in a backside inter-metal dielectric (IMD) layer 302. A backside power rail 301P of the backside metal lines 301 is connected to one of the source/drain epitaxial structures 180 through the backside source/drain contacts VB, so as to provide a routing space for the semiconductor device 100E from the backside of the substrate 110. As illustrated in FIG. 24, the backside gate contacts VG may extend through the isolation layers 310 to the gate structures 220.

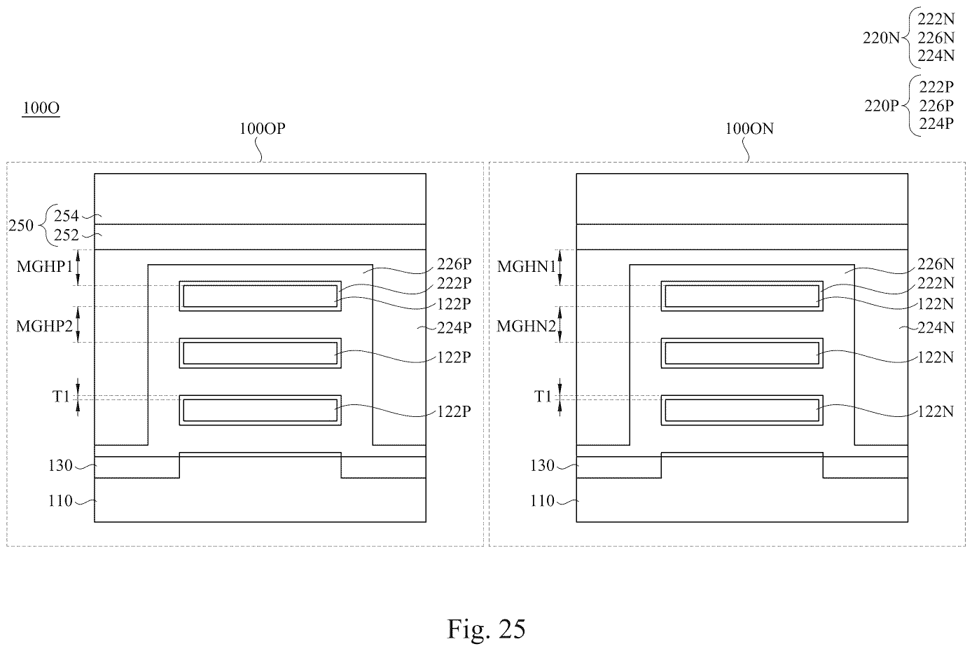

In one or more embodiments of the present disclosure, heights of the outer gate portions of the gate structures 220 of a formed semiconductor device can be controlled at different regions. Reference is made to FIG. 25. FIG. 25 illustrates cross-sectional views of a p-type FET region 100OP and an n-type FET region 100ON of a semiconductor device 100O in accordance with some embodiments of the present disclosure, wherein FIG. 25 illustrates cross-sectional views of a p-type FET region 100OP and an n-type FET region 100ON of a semiconductor device 100O along the gate structures 220 including a gate structure 220P in the p-type FET region 100OP and a gate structure 220N in the n-type FET region 100ON.

As illustrated in FIG. 25, in the p-type FET region 100OP, the semiconductor device 100O includes channel layers 122P and the gate structure 220P around the channel layers 122P. The gate structure 220P may include a gate dielectric layer 222P around the channel layers 122P, a work function metal stack 226P over the gate dielectric layer 222P and the gate metal layer 224P over the work function metal stack 226P. The dielectric material 250 including an etch stop layer 252 and an ILD layer 254 are over the gate structure 220P. The gate structure 220P may have a height MGHP1 of an outer gate portion above the topmost channel layer 122P and a height MGHP2 between the channel regions. In one or more embodiments of the present disclosure, the height MGHP1 may be substantially equal to or less than the height MGHP2.

In the n-type FET region 100ON, the semiconductor device 100O includes channel layers 122N and the gate structure 220 N around the channel layers 122N. The gate structure 220N may include a gate dielectric layer 222N around the channel layers 122N, a work function metal stack 226N over the gate dielectric layer 222N and the gate metal layer 224N over the work function metal stack 226N. The dielectric material 250 including an etch stop layer 252 and an ILD layer 254 are over the gate structure 220N. The gate structure 220N may have a height MGHN1 of an outer gate portion above the topmost channel layer 122P and a height MGHN2 between the channel regions. In one or more embodiments of the present disclosure, the height MGHN1 may be substantially equal to or less than the height MGHN2.

In some embodiments, the height MGHP1 of the outer gate portion of the gate structure 220P may be different from the height MGHN1 of the outer gate portion of the gate structure 220N.

In some embodiments, a composition of the work function metal stack 226P of the gate structure 220P may be different from a composition of the work function metal stack 226N of the gate structure 220N. For an n-type GAA FET, the gate metal layer 226N may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 226P may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, one or more dipole layers may be formed in the gate dielectric layers 222P and the 222N, and the gate dielectric layers 222P and the 222N may be treated and be doped through dipole dopant of the dipole layers. In some embodiments, the gate dielectric layers 222P and the 222N may different dipole dopant concentrations, and the compositions of the work function metal stacks 226P and 226N may be the same.

Each of the gate dielectric layers 222P and 222N may include an interfacial layer and a high-k gate dielectric layer over the interfacial layer. In some embodiments, a thickness T1 of the gate dielectric layer 222P may be different from a thickness T2 of the gate dielectric layer 222N.

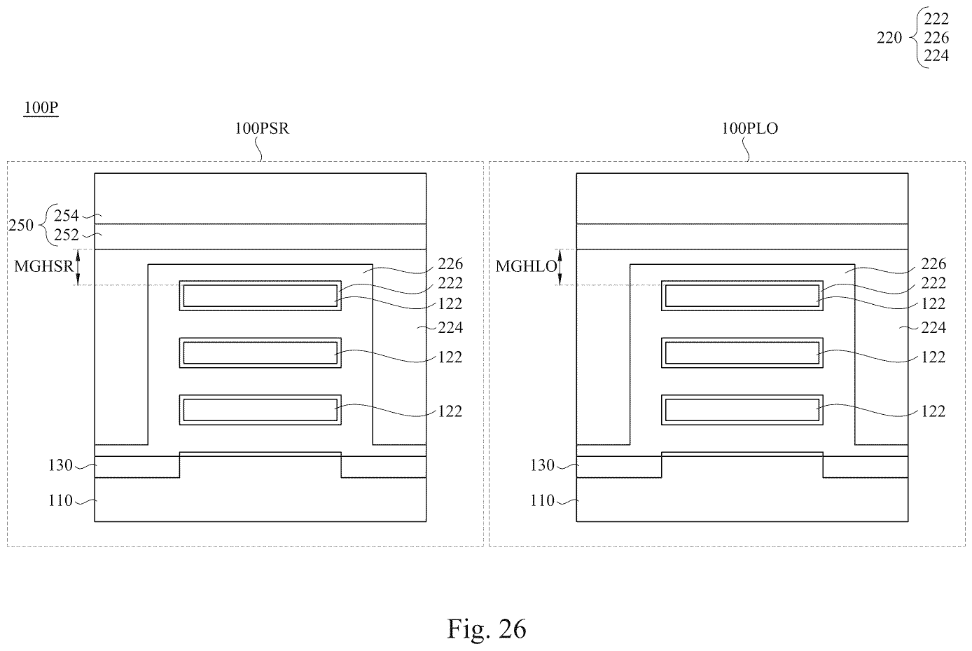

Reference is made to FIG. 26. FIG. 26 illustrates cross-sectional views of a memory region 100PSR and a logic region 100PLO of a semiconductor device 100P along the gate structures 220 in accordance with some embodiments of the present disclosure.

In some embodiments, the semiconductor device 100P may include GAA FET used for memory cells such as static random-access memory (SRAM) cells in the memory region 100PSR. In some embodiments, the semiconductor device 100P may include GAA FET used for logic circuits. As illustrated in FIG. 26, the semiconductor device 100P in each of the memory region 100PSR and the logic region 100PLO may include channel layers 122 over the substrate 110, the gate structure 220 around the channel layers 122 and the dielectric material 250 over the gate structure 220. In some embodiments, the gate structure 220 may include a gate dielectric layer 222 around the channel layers 122, a work function metal stack 226 over the gate dielectric layer 222 and the gate metal layer 224 over the work function metal stack 226. The dielectric material 250 may include an etch stop layer (ESL) 252 and an ILD layer 254 over the ESL 252.

As illustrated in FIG. 26, the outer gate portion of the gate structure 220 above the topmost channel layer 122 may have a height MGHSR in the memory region 100PSR, and the outer gate portion of the gate structure 220 above the topmost channel layer 122 may have a height MGHLO in the logic region 100PLO.

In some embodiments, for reduction of the effective parasitic capacitance caused by the gate structure 220 and the source/drain contacts (not illustrated) in the logic region 100PLO, the height MGHLO of the outer gate portion of the gate structure 220 in the logic region 100PLO may be greater than the height MGHSR of the outer gate portion of the gate structure 220 in the memory region 100PSR. In some embodiments, for reduction of the resistance of the gate metal layer 224 in the logic region 100PLO, the height MGHLO of the outer gate portion of the gate structure 220 in the logic region 100PLO may be less than the height MGHSR of the outer gate portion of the gate structure 220 in the logic region 100PLO. In some embodiments, a difference between the height MGHLO in the logic region 100PLO and the height MGHSR in the memory region 100PSR may in a range from about 0.5 nm to about 5 nm.

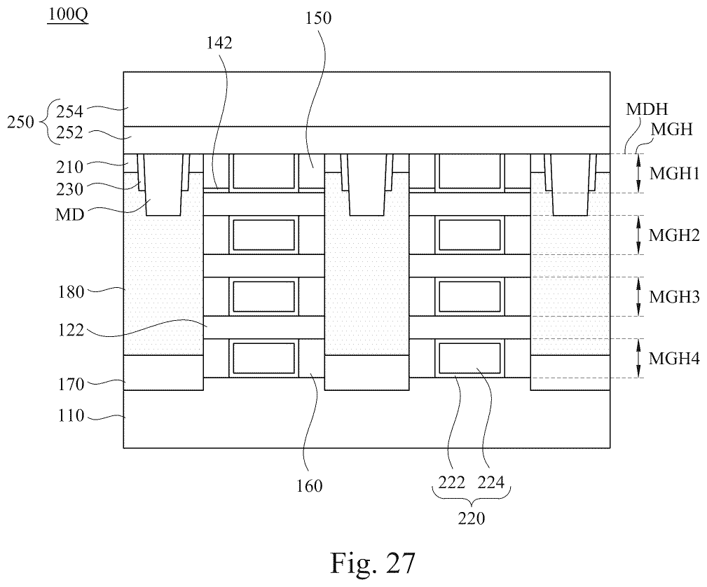

Reference is made to FIG. 27. FIG. 27 is a cross-sectional view of a semiconductor device 100Q in accordance with some embodiments of the present disclosure. FIG. 27 is a cross-sectional view of the semiconductor device 100A along the channel layers 122. Details of the present embodiments are similar to those illustrated in FIGS. 1-9B.

As illustrated in FIGS. 9A and 27, the semiconductor device 100Q may be substantially the same as the semiconductor device 100, except that the gate dielectrics 142 of the semiconductor device 100Q extend below the gate spacers 150. In FIG. 27, the gate dielectrics 142 may be dummy oxide layers extending below the gate spacers 150. For example, in some embodiments, a poly (e.g., poly gate electrode 144) patterning without dummy oxide (e.g., the gate dielectrics 142) patterning, followed by spacer material (e.g., the gate spacers 150) deposition, followed by spacer patterning and dummy oxide patterning, is performed. In some embodiments, the gate spacers 150 may be formed over the gate dielectric 142. In some embodiments, after the dummy gate structures 140 (see FIG. 3B) is removed and replacement gate structure are formed in the subsequent processes, portions of the gate dielectrics 142 remain and can be served as portions of the gate spacers 150 on opposite sides of the formed replacement gate structures 220.

According to one or more embodiments of the present disclosure, a method of forming a semiconductor device includes a number of operations. A plurality of channel layers is vertically arranged over a substrate. Source/drain regions are formed on opposite sides of the channel layers. A gate structure is formed and wraps around the channel layers. A planarization process is performed on the gate structure such that a first portion of the gate structure above a topmost one of the channel layers has a first height less than or equal to a second height of a second portion of the gate structure between the channel layers. Source/drain contacts are formed over the source/drain regions. In one or more embodiments of the present disclosure, the method further includes forming a first dielectric material over the source/drain regions, wherein the source/drain contacts extend through the first dielectric material to the source/drain regions. In some embodiments, the method further includes forming a etch stop layer over the first dielectric material and the gate structure, wherein the source/drain contacts extend through the etch stop layer. In some embodiments, the method further includes forming a second dielectric material over the first dielectric material and the gate structure, wherein the source/drain contacts extend through the second dielectric material. In some embodiments, the method further includes forming a third dielectric material over the second dielectric material, wherein the source/drain contacts extend through the third dielectric material. In some embodiments, the method further includes forming barrier layers in the first dielectric material, wherein the barrier layers are formed on sidewalls of the source/drain contacts, and top surfaces of the barrier layers are level with top surfaces of the source/drain contacts. In one or more embodiments of the present disclosure, the gate structure includes a high-k/metal gate structure.

According to one or more embodiments of the present disclosure, a method of forming a semiconductor device includes a number of operations. An epitaxial stack is formed over a substrate, wherein the epitaxial stack comprises semiconductor layers and sacrificial layers alternatively arranged with each other. Source/drain regions are formed on opposite sides of channel layers. A dummy gate structure is formed over the epitaxial stack. The dummy gate structure and the sacrificial layers are replaced with a gate structure. A first planarization process is performed on the gate structure so that a height of an outer gate portion of the gate structure above a topmost one of the channel layers is reduced to be less than or equal to a height of an inner gate portion between the channel layers. After performing the first planarization process on the gate structure, source/drain contacts are over the source/drain regions. A second planarization process is performed on the source/drain contacts. In one or more embodiments of the present disclosure, the planarized gate structure is exposed after performing the second planarization process on the source/drain contacts. In one or more embodiments of the present disclosure, the method further includes forming an etch stop layer over the planarized gate structure, wherein the second planarization process performed on the source/drain contacts stops at the etch stop layer. In one or more embodiments of the present disclosure, the method further includes forming a first dielectric material over the source/drain regions and forming a second dielectric material over the first dielectric material and the planarized gate structure, wherein the source/drain contacts extend through the first and second dielectric material to the source/drain regions. In some embodiments, the method further includes forming a third dielectric material over the second dielectric material, wherein the source/drain contacts extend through the third dielectric material. In one or more embodiments of the present disclosure, the method further includes forming a backside power rail connected to one the source/drain regions from a backside of the substrate. In one or more embodiments of the present disclosure, the method further includes forming a backside gate contacts connected the planarized gate structure from a backside of the substrate.

According to one or more embodiments of the present disclosure, a semiconductor device includes a plurality channel layers, source/drain regions, a gate structure, a dielectric material and source/drain contacts. The channel layers are vertically arranged over a substrate. The source/drain regions are on opposite sides of the channel layers. The gate structure wraps around the channel layers. A first portion of the gate structure above a topmost one of the channel layers has a first height less than or equal to a second height of a second portion of the gate structure between the channel layers. The dielectric material is over the source/drain regions. The source/drain contacts are through the dielectric material to the source/drain regions. In one or more embodiments of the present disclosure, the semiconductor device further includes barrier layers. The barrier layers are on sidewalls of the source/drain contacts. Top surfaces of the barrier layers are level with top surfaces of the source/drain contacts. In one or more embodiments of the present disclosure, a topmost surface of the gate structure is lower than a top surface of one of the source/drain contacts. In one or more embodiments of the present disclosure, a topmost surface of the gate structure is level with a top surface of one of the source/drain contacts. The bottom isolation layers are below the source/drain regions. The backside source/drain contacts are through the substrate and the bottom isolation layers. The backside power rail is connected to one of the source/drain regions by one of the backside source/drain contacts. In one or more embodiments of the present disclosure, the semiconductor device further includes bottom isolation layers, backside source/drain contacts and a backside power rail. In one or more embodiments of the present disclosure, the gate structure comprises a high-k/metal gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of channel layers vertically arranged over a substrate;
forming source/drain regions on opposite sides of the channel layers;
forming a gate structure wrapping around the channel layers;
performing a planarization process on the gate structure such that a first portion of the gate structure above a topmost one of the channel layers has a first height less than or equal to a second height of a second portion of the gate structure between the channel layers; and
forming source/drain contacts over the source/drain regions.

2. The method of claim 1, further comprising:
forming a first dielectric material over the source/drain regions, wherein the source/drain contacts extend through the first dielectric material to the source/drain regions.

3. The method of claim 2, further comprising:
forming a etch stop layer over the first dielectric material and the gate structure, wherein the source/drain contacts extend through the etch stop layer.

4. The method of claim 2, further comprising:
forming a second dielectric material over the first dielectric material and the gate structure, wherein the source/drain contacts extend through the second dielectric material.

5. The method of claim 4, further comprising:
forming a third dielectric material over the second dielectric material, wherein the source/drain contacts extend through the third dielectric material.

6. The method of claim 2, further comprising:
forming barrier layers in the first dielectric material, wherein the barrier layers are formed on sidewalls of the source/drain contacts, and top surfaces of the barrier layers are level with top surfaces of the source/drain contacts.

7. The method of claim 1, wherein the gate structure comprises a high-k/metal gate structure.

8. A method comprising:
forming an epitaxial stack over a substrate, wherein the epitaxial stack comprises semiconductor layers and sacrificial layers alternatively arranged with each other;
forming source/drain regions on opposite sides of channel layers;
forming a dummy gate structure over the epitaxial stack;
replacing the dummy gate structure and the sacrificial layers with a gate structure;
performing a first planarization process on the gate structure so that a height of an outer gate portion of the gate structure above a topmost one of the channel layers is reduced to be less than or equal to a height of an inner gate portion between the channel layers;
after performing the first planarization process on the gate structure, forming source/drain contacts over the source/drain regions; and
performing a second planarization process on the source/drain contacts.

9. The method of claim 8, wherein the planarized gate structure is exposed after performing the second planarization process on the source/drain contacts.

10. The method of claim 8, further comprising:
forming an etch stop layer over the planarized gate structure, wherein the second planarization process performed on the source/drain contacts stops at the etch stop layer.

11. The method of claim 8, further comprising:
forming a first dielectric material over the source/drain regions; and
forming a second dielectric material over the first dielectric material and the planarized gate structure, wherein the source/drain contacts extend through the first and second dielectric material to the source/drain regions.

12. The method of claim 11, further comprising:
forming a third dielectric material over the second dielectric material, wherein the source/drain contacts extend through the third dielectric material.

13. The method of claim 8, further comprising:
forming a backside power rail connected to one the source/drain regions from a backside of the substrate.

14. The method of claim 8, further comprising:
forming a backside gate contacts connected the planarized gate structure from a backside of the substrate.

15. A semiconductor device, comprising:
a plurality channel layers vertically arranged over a substrate;
source/drain regions on opposite sides of the channel layers;
a gate structure wrapping around the channel layers, wherein a first portion of the gate structure above a topmost one of the channel layers has a first height less than or equal to a second height of a second portion of the gate structure between the channel layers;
a dielectric material over the source/drain regions; and
source/drain contacts through the dielectric material to the source/drain regions.

16. The semiconductor device of claim 15, further comprising:
barrier layers on sidewalls of the source/drain contacts, wherein top surfaces of the barrier layers are level with top surfaces of the source/drain contacts.

17. The semiconductor device of claim 15, wherein a topmost surface of the gate structure is lower than a top surface of one of the source/drain contacts.

18. The semiconductor device of claim 15, wherein a topmost surface of the gate structure is level with a top surface of one of the source/drain contacts.

19. The semiconductor device of claim 15, further comprising:
bottom isolation layers below the source/drain regions;
backside source/drain contacts through the substrate and the bottom isolation layers; and
a backside power rail connected to one of the source/drain regions by one of the backside source/drain contacts.

20. The semiconductor device of claim 15, wherein the gate structure comprises a high-k/metal gate structure.
